(19) United States
(12) Patent Application Publication
(10) Pub. No.: US 2024/0244928 A1
(43) Pub. Date: Jul. 18, 2024

(54) DISPLAY APPARATUS AND METHOD OF MANUFACTURING THE SAME

(71) Applicant: Samsung Display Co., LTD., Yongin-si (KR)

(72) Inventors: Seongwon KIM, Yongin-si (KR); Dongchul SHIN, Yongin-si (KR); Jangyeol YOON, Yongin-si (KR)

(21) Appl. No.: 18/407,041

(22) Filed: Jan. 8, 2024

(30) Foreign Application Priority Data
Jan. 13, 2023 (KR) 10-2023-0005637

(51) Int. Cl. H10K 59/80; H10K 59/12; H10K 59/131; H10K 59/88; H10K 77/10; H10K 102/00

(52) U.S. Cl. CPC H10K 59/873; H10K 59/1201; H10K 59/131; H10K 59/88; H10K 77/111; H10K 2102/311; H10K 2102/351

(57) ABSTRACT

A display apparatus including a display panel in which a penetration-opening portion is defined includes: a substrate layer including a first display portion, a second display portion, and a connection portion connecting the first display portion to the second display portion; a side-wall groove defined in the substrate layer and recessed from a lower surface of the substrate layer; a pixel arranged on the first display portion; and a line arranged on the connection portion and configured to transfer an electrical signal.

This application claims priority to Korean Patent Application No. 10-2023-0005637, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the same.

### 2. Description of the Related Art

A mobile electronic device has become widely used. As the mobile electronic device, a tablet personal computer (“PC”) has become broadly used recently, in addition to a small electronic device, such as a mobile phone.

Such a mobile electronic device includes a display in order to provide a user with various functions, for example, visual information such as an image or a video. As various components for driving a display apparatus have been miniaturized, the importance of the display apparatus in an electronic device has been increasing.

A flexible display apparatus that is bendable, foldable, or rollable have been researched and developed. Furthermore, a stretchable display apparatus that can be changed to various shapes has been actively researched and developed.

### SUMMARY

One or more embodiments include a display apparatus with increased flexibility.

Additional aspects will be set forth in part in the description which follows and, in part, will be apparent from the description, or may be learned by practice of the presented embodiments of the disclosure.

According to one or more embodiments, a display apparatus including a display panel in which a penetration-opening portion is defined includes a substrate layer including a first display portion, a second display portion, and a connection portion connecting the first display portion to the second display portion, a side-wall groove defined in the substrate layer and recessed from a lower surface of the substrate layer, a pixel arranged on the first display portion, and a line arranged ion the connection portion and configured to transfer an electrical signal.

At least a portion of the side-wall groove may be provided along a circumference of the first display portion.

At least a portion of the side-wall groove may be provided along a circumference of the connection portion.

The display apparatus may further include an encapsulation layer covering the pixel.

A height of the side-wall groove may be greater than or equal to 150% of a reference thickness of the encapsulation layer and less than or equal to 50% of a reference thickness of the substrate layer measured in a portion of the substrate layer where the side-wall groove is not defined.

A depth of the side-wall groove in a side direction may be greater than or equal to 6 micrometers (μm) and less than or equal to 25% of a reference width of the substrate layer in the side direction and measured in a portion of the substrate layer where the side-wall groove is not defined.

The side-wall groove may be provided to have a quadrangular, triangular, curved, or stair shape.

The pixel may include a first electrode, an emission layer arranged on the first electrode, and a second electrode arranged on the emission layer.

The display apparatus may further include a capping layer arranged on the second electrode.

The capping layer may be provided between the second electrode and the encapsulation layer.

The display apparatus may further include a first insulating layer arranged on the first display portion of the substrate layer and including a first tip protruding toward the penetration-opening portion.

The display apparatus may further include a second insulating layer arranged on the first insulating layer and a third insulating layer arranged on the second insulating layer and including a second tip protruding toward the penetration-opening portion.

According to one or more embodiments, a method of manufacturing a display apparatus includes preparing a carrier substrate including a display area, a connection area, a dummy area, and a cut area, forming a substrate layer on the carrier substrate, forming a first insulating layer on the substrate layer, forming a first electrode on the first insulating layer in the display area, and removing the first insulating layer and the substrate layer in the cut area and forming a side-wall groove in the substrate layer in the display area and the connection area.

The side-wall groove may overlap the display area in a plan view, and at least a portion of the side-wall groove may be formed along a circumference of the display area.

The side-wall groove may overlap the connection area in a plan view, and at least a portion of the side-wall groove may be formed along a circumference of the connection area.

The method may further include, after the removing of the first insulating layer and the substrate layer in the cut area and the forming of the side-wall groove in the substrate layer in the display area and the connection area, forming an emission layer on the first electrode, forming a second electrode on the emission layer, forming a capping layer on the second electrode, and forming an encapsulation layer on the capping layer.

The encapsulation layer may be formed throughout the display area, the connection area, the dummy area, and the cut area.

A height of the side-wall groove may be greater than or equal to 150% of a reference thickness of the encapsulation layer and less than or equal to 50% of a reference thickness of the substrate layer measured in a portion of the substrate layer where the side-wall groove is not defined.

A depth of the side-wall groove in a side direction may be greater than or equal to 6 μm and less than or equal to 25% of a reference width of the substrate layer in the side direction and measured in a portion of the substrate layer where the side-wall groove is not defined.

The side-wall groove may be provided to have a quadrangular, triangular, curved, or stair shape.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a display apparatus according to an embodiment;

FIG. 2 is a schematic plan view of a display apparatus according to an embodiment;

FIG. 3 is a schematic equivalent circuit diagram of a pixel circuit applicable to a display apparatus, according to an embodiment;

FIG. 4 is a schematic plan view of a display apparatus according to an embodiment;

FIGS. 5 and 6 are schematic cross-sectional views of a display apparatus according to an embodiment;

FIG. 7 is a schematic plan view of a display apparatus according to an embodiment;

FIG. 8 is a schematic cross-sectional view of a display apparatus according to an embodiment;

FIGS. 9 and 10 are views for describing a thickness tendency of an encapsulation layer according to a depth of a side-wall groove; and

FIGS. 11 to 28 are schematic cross-sectional views for describing a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are illustrated in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In this specification, the expression “A and/or B” may indicate A, B, or A and B. Also, in this specification, the expression “at least one of A and B” may indicate A, B, or A and B.

In embodiments described hereinafter, “lines extending in a first direction or a second direction” denotes not only the lines extending as a linear shape, but also the lines extending in the first direction or the second direction as a zig-zag shape or a curved shape.

In the embodiments hereinafter, the expression “planar” indicates a shape when an object is seen downwardly, and the expression “cross-sectional” indicates a shape when an object, which is vertically taken, is seen from the lateral perspective. In the embodiments below, when a part is referred to as “overlapping,” the part may be “planarly” or “cross-sectionally” overlapping.

Hereinafter, embodiments of the disclosure will be described in detail with reference to the accompanying drawings. Also, when the descriptions are given by referring to the drawings, the same elements or the corresponding elements will be referred to by using the same reference numerals.

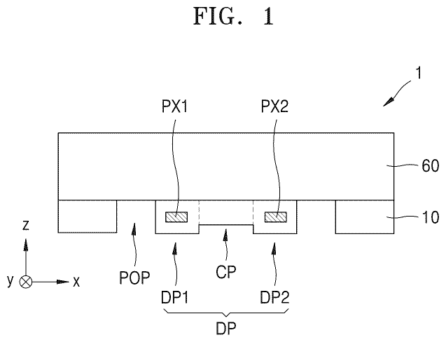

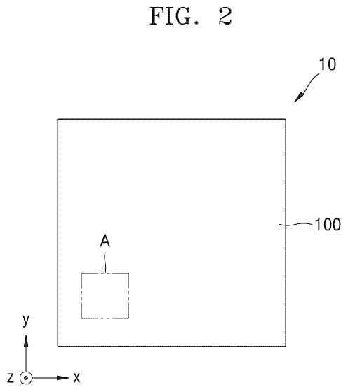

FIG. 1 is a schematic cross-sectional view of a display apparatus 1 according to an embodiment, and FIG. 2 is schematic plan view of the display apparatus 1 according to an embodiment. As used herein, the “plan view” is a view in a thickness direction (i.e., z direction) of the substrate layer 100.

Referring to FIG. 1, the display apparatus 1 may include a display panel 10 and a cover window 60. The cover window 60 may be arranged on the display panel 10.

The display panel 10 may display an image. The display panel 10 may include a plurality of pixels, for example, a first pixel PX1 and a second pixel PX2. The display panel 10 may display an image by using the plurality of pixels.

Each of the plurality of pixels may include a display element. The display panel 10 may include an organic light-emitting display panel using an organic light-emitting diode including an organic emission layer. Alternatively, the display panel 10 may include a light-emitting diode display panel using a light-emitting diode A size of the light-emitting diode may be a micro-scale or a nano-scale, and for example, the light-emitting diode may include a micro-light-emitting diode. Alternatively, the light-emitting diode may include a nanorod-light-emitting diode. The nanorod-light-emitting diode may include GaN. According to an embodiment, a color conversion layer may be arranged on the nanorod-light-emitting diode. The color conversion layer may include quantum dots. Alternatively, the display panel 10 may include a quantum dot light-emitting display panel using a quantum dot light-emitting diode. Alternatively, the display panel 10 may include an inorganic light-emitting display panel using an inorganic light-emitting diode including an inorganic semiconductor. Hereinafter, a case where the display panel 10 includes an organic light-emitting display panel using an organic light-emitting diode as a display element will be mainly described in detail.

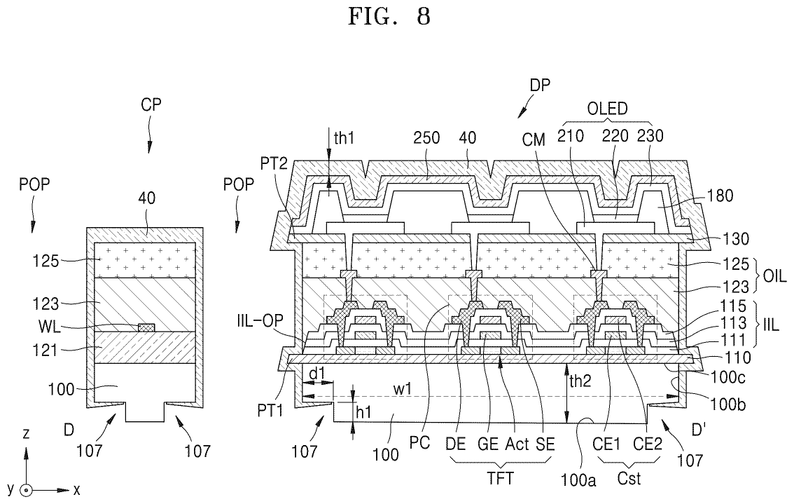

The display panel 10 may include a display portion DP, a connection portion CP, and a penetration-opening portion POP. The display portion DP may include a first display portion DP1 and a second display portion DP2. However, the display panel 10 includes a substrate layer 100 (see FIG. 8), and thus, it may be understood that the substrate layer 100 may include the display portion DP, the connection portion CP, and the penetration-opening portion POP.

The first pixel PX1 may be arranged in the first display portion DP1, and the second pixel PX2 may be arranged in the second display portion DP2. The connection portion CP may be arranged between the first display portion DP1 and the second display portion DP2 and may connect the first display portion DP1 and the second display portion DP2 to each other. A pixel may not be arranged in the connection portion CP.

The penetration-opening portion POP (or a cut portion) may be defined in the display panel 10. The penetration-opening portion POP may penetrate through the display panel 10. The penetration-opening portion POP may be an area, in which components of the display panel 10 are not arranged. The display panel 10 may include a plurality of penetration-opening portions POP. Thus, the display panel 10 may be easily stretched and/or contracted.

The cover window 60 may protect the display panel 10. According to an embodiment, the cover window 60 may protect the display panel 10 by being easily bent according to an external force without cracks, etc. generated. The cover window 60 may be bonded to the display panel 10 by a transparent adhesive member, such as an optically clear adhesive (“OCA”) film.

The cover window 60 may include glass, sapphire, or plastic. The cover window 60 may include, for example, ultra-thin glass (“UTG”) or colorless polyimide (“CPI”). According to an embodiment, the cover window 60 may have a structure in which a flexible polymer layer is arranged on a surface of a glass substrate or may have a structure including only a polymer layer.

Referring to FIG. 2, the display panel 10 may include the substrate layer 100 and layers arranged on the substrate layer 100. According to an embodiment, the display panel 10 may include the penetration-opening portion POP (see FIG. 1). The substrate layer 100 and the layers may not be arranged in the penetration-opening portion POP. That is, the penetration-opening portion POP may be an empty area of the display panel 10. The penetration-opening portion POP may be provided in the display panel 10 in a plurality. Because the plurality of penetration-opening portions POP may be provided in the display panel 10, the flexibility of the display apparatus 1 (see FIG. 1) including the display panel 10 may be improved.

The substrate layer 100 may include glass or polymer resins, such as polyether sulfone, polyarylate, polyether imide, polyethylene naphthalate, polyethylene terephthalate, polyphenylene sulfide, polyimide, polycarbonate, cellulose triacetate, and cellulose acetate propionate. The substrate layer 100 including the polymer resins may be flexible, rollable, or bendable. The substrate layer 100 may have a single-layered structure including the polymer resins described above. When the substrate layer 100 is provided as a single-layered structure, the flexibility of the display apparatus 1 including the substrate layer 100 may be improved. However, the disclosure is not limited thereto. The substrate layer 100 may have a layered structure including a base layer including the polymer resins described above and a barrier layer.

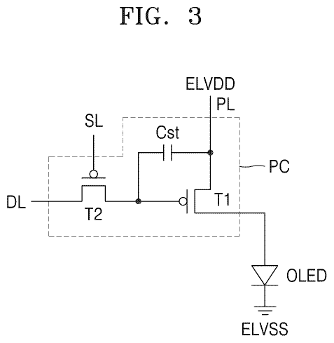

FIG. 3 is a schematic equivalent circuit diagram of a pixel circuit PC applicable to a display apparatus, according to an embodiment.

Referring to FIG. 3, the pixel circuit PC may be connected to a display element, for example, an organic light-emitting diode OLED. The pixel circuit PC may include a driving thin-film transistor T1, a switching thin-film transistor T2, and a storage capacitor Cst. The organic light-emitting diode OLED may emit red, green, or blue light or red, green, blue, or white light.

The switching thin-film transistor T2 may be connected to a scan line SL and a data line DL and may be configured to transmit a data signal or a data voltage input through the data line DL, to the driving thin-film transistor T1, in response to a scan signal or a switching voltage input through the scan line SL. The storage capacitor Cst may be connected to the switching thin-film transistor T2 and a driving voltage line PL and may be configured to store a voltage corresponding to a difference between a voltage received from the switching thin-film transistor T2 and a first power voltage ELVDD supplied to the driving voltage line PL.

The driving thin-film transistor T1 may be connected to the driving voltage line PL and the storage capacitor Cst and may be configured to control a driving current flowing from the driving voltage line PL through the organic light-emitting diode OLED according to a value of the voltage stored in the storage capacitor Cst. The organic light-emitting diode OLED may emit light having a certain brightness according to the driving current. An opposite electrode of the organic light-emitting diode OLED may receive a second power voltage ELVSS.

FIG. 3 illustrates that the pixel circuit PC includes two thin-film transistors and one storage capacitor. However, the pixel circuit PC may include three, four, five, or more thin-film transistors.

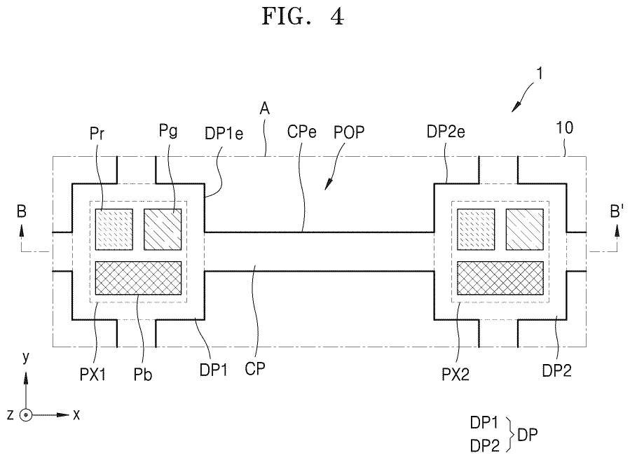

FIG. 4 is a schematic plan view of the display apparatus 1 according to an embodiment. FIG. 4 is an enlarged view of region A of FIG. 2.

Referring to FIG. 4, the display panel 10 included in the display apparatus 1 may include the display portion DP and the connection portion CP. The display portion DP may include the first display portion DP1 and the second display portion DP2. According to an embodiment, the display panel 10 may include a plurality of first display portions DP1 and a plurality of second display portions DP2. Also, the display panel 10 may include a plurality of connection portions CP.

The first pixel PX1 may be arranged in the first display portion DP1. The first display portion DP1 may be apart from the second display portion DP2 with the connection portion CP therebetween. The first display portion DP1 may be connected to the connection portion CP. According to an embodiment, the first display portion DP1 may be connected to at least one connection portion CP.

The second pixel PX2 may be arranged in the second display portion DP2. The second display portion DP2 may be apart from the first display portion DP1. The second display portion DP2 may be connected to the connection portion CP. According to an embodiment, the second display portion DP2 may be connected to at least one connection portion CP. The second display portion DP2 may be provided to have the same or substantially the same structure as the first display portion DP1.

The connection portion CP may extend from the first display portion DP1 to the second display portion DP2. The first display portion DP1 and the second display portion DP2 may be connected to each other by the connection portion CP. According to an embodiment, when the display apparatus 1 includes the plurality of connection portions CP, the plurality of connection portions CP may be connected to the first display portion DP1 and/or the second display portion DP2. Some of the plurality of connection portions CP may connect the first display portion DP1 and/or the second display portion DP2 to other display portions.

Any one of the plurality of connection portions CP may extend in a first direction. Another of the plurality of connection portions CP may extend in a second direction crossing the first direction. According to an embodiment, the first direction and the second direction may be orthogonal to each other. For example, the first direction may be a +x direction or a −x direction of FIG. 4, and the second direction may be a +y direction or a −y direction of FIG. 4. Alternatively, the first and second directions may form an acute angle or an obtuse angle with each other. Hereinafter, a case where the first direction (for example, the +x direction or the −x direction) and the second direction (for example, the +y direction or the −y direction) are orthogonal to each other is mainly described in detail.

According to an embodiment, the first display portion DP1 and the connection portion CP may be defined as one basic unit. In this case, the basic unit may be repeatedly arranged in the first direction (for example, the +x direction or the −x direction) and/or the second direction (for example, the +y direction or the −y direction), and it may be understood that the display panel 10 may include the repeatedly arranged basic units that are connected to each other.

The penetration-opening portion POP may be defined in the display panel 10. The penetration-opening portion POP may penetrate through the display panel 10. Thus, the penetration-opening portion POP may be an area where components of the display panel 10 are not arranged. The display panel 10 may include the plurality of penetration-opening portions POP. Thus, the flexibility of the display panel 10 may be increased.

At least a portion of the penetration-opening portion POP may be defined by an edge DP1e of the first display portion DP1, an edge DP2e of the second display portion DP2, and an edge CPe of the connection portion CP. According to an embodiment, the penetration-opening portion POP may have a closed-curve shape. Alternatively, the penetration-opening portion POP may have a shape that is at least partially open.

A width of the connection portion CP may be less than a width of the first display portion DP1 and a width of the second display portion DP2. Thus, even when a strain occurs in the connection portion CP, a maximum value of the strain occurring in the connection portion CP may be reduced.

Each of the first pixel PX1 and the second pixel PX2 may include a red sub-pixel Pr, a green sub-pixel Pg, and a blue sub-pixel Pb. The red sub-pixel Pr, the green sub-pixel Pg, and the blue sub-pixel Pb may emit red light, green light, and blue light, respectively. Alternatively, each of the first pixel PX1 and the second pixel PX2 may include a red sub-pixel Pr, a green sub-pixel Pg, a blue sub-pixel Pb, and a white sub-pixel. The red sub-pixel Pr, the green sub-pixel Pg, the blue sub-pixel Pb, and the white sub-pixel may emit red light, green light, blue light, and white light, respectively. Hereinafter, a case where each of the first pixel PX1 and the second pixel P2 includes the red sub-pixel Pr, the green sub-pixel Pg, and the blue sub-pixel Pb is mainly described in detail.

According to an embodiment, the red sub-pixel Pr and the green sub-pixel Pg may be arranged as a quadrangular shape, and the blue sub-pixel Pb may be arranged as a quadrangular shape having a long side in the first direction (for example, the +x direction or the −x direction). In other words, a side of the red sub-pixel Pr and a side of the green sub-pixel Pg may face a long side of the blue sub-pixel Pb. According to an embodiment, the red sub-pixel Pr and the green sub-pixel Pg may be arranged in a first row, and the blue-sub pixel Pb may be arranged in a second row adjacent to the first row.

Alternatively, the sub-pixel arrangement structure of the first pixel PX1 may be an S-stripe structure. For example, the blue sub-pixel Pb may be arranged in a first column, and the red sub-pixel Pr and the green sub-pixel Pg may be arranged in a second column adjacent to the first column. Here, the blue sub-pixel Pb may be arranged as a quadrangular shape having a long side in the second direction (for example, the +y direction or the −y direction), and the red sub-pixel Pr and the green sub-pixel Pg may be arranged as a quadrangular shape.

Alternatively, the sub-pixel arrangement structure of the first pixel PX1 may be a stripe structure. For example, the red sub-pixel Pr, the green sub-pixel Pg, and the blue sub-pixel Pb may be arranged in parallel in the first direction (for example, the +x direction or the −x direction) or the second direction (for example, the +y direction or the −y direction). Alternatively, the sub-pixel arrangement structure of the first pixel PX1 may be a pentile™ structure.

The edge CPe of the connection portion CP may extend in an extension direction of the connection portion CP. For example, when the connection portion CP extends in the first direction (for example, the +x direction or the −x direction), the edge CPe of the connection portion CP may also extend in the first direction (for example, the +x direction or the −x direction). Also, when the connection portion CP extends in the second direction (for example, the +y direction or the −y direction), the edge CPe of the connection portion CP may also extend in the second direction (for example, the +y direction or the −y direction).

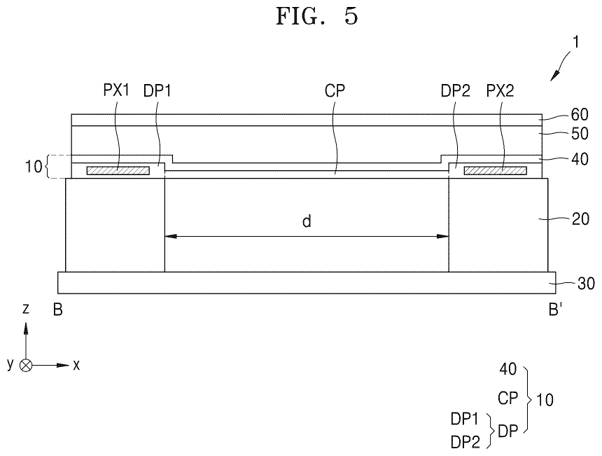

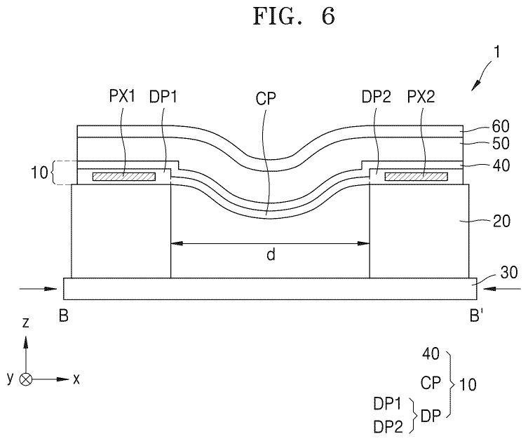

FIGS. 5 and 6 are schematic cross-sectional views of the display apparatus 1 according to an embodiment.

In detail, FIGS. 5 and 6 are cross-sectional views of the display apparatus 1 taken along line B-B′ of FIG. 4, wherein FIG. 5 illustrates the display apparatus 1 before an external force is applied thereto, and FIG. 6 illustrates the display apparatus 1 after an external force is applied thereto.

Referring to FIG. 5, the display apparatus 1 may include the display panel 10, a pillar layer 20, a flexible substrate 30, an optical functional layer 50, and the cover window 60.

The display panel 10 may include the display portion DP, the connection portion CP, and an encapsulation layer 40, and the display portion DP may include the first display portion DP1 and the second display portion DP2. Also, the first pixel PX1 may be arranged in the first display portion DP1, and the second pixel PX2 may be arranged in the second display portion DP2. The first display portion DP1 and the second display portion DP2 may be portions displaying an image through the first pixel PX1 and the second pixel PX2, respectively. The connection portion CP may connect the first display portion DP1 with the second display portion DP2. The first display portion DP1 and the second display portion DP2 may be connected with each other by the connection portion CP.

As illustrated in FIG. 8 to be described below, the display portion DP of the display panel 10 may include insulating layers. Some of the insulating layers included in the first display portion DP1 may be omitted in the connection portion CP. Thus, because some of the insulating layers may be omitted in the connection portion CP, a thickness of the connection portion CP may be less than a thickness of the display portion DP.

The pillar layer 20 may be arranged below the display panel 10. The pillar layer 20 may support the display panel 10. Even when the external force is applied to the display apparatus 1, a shape of the pillar layer 20 may not be changed.

According to an embodiment, the pillar layer 20 may be arranged below the display portion DP of the display panel 10. That is, the pillar layer 20 may overlap the display portion DP and may not overlap the connection portion CP. A plurality of pillar layers 20 may be arranged to be apart from each other. The plurality of pillar layers 20 may be respectively arranged below the plurality of display portions DP apart from each other.

The flexible substrate 30 may be arranged below the pillar layer 20. The flexible substrate 30 may overlap the display portion DP and the connection portion CP. The flexible substrate 30 may include a flexible material. The flexible substrate 30 may be more flexible than the pillar layer 20.

The encapsulation layer 40 may be arranged on the display portion DP and the connection portion CP. According to an embodiment, the encapsulation layer 40 may include a thin-film encapsulation layer. The encapsulation layer 40 may cover the pixels PX1 and PX2. According to an embodiment, the encapsulation layer 40 may include at least one inorganic layer. The at least one inorganic layer may include one or more inorganic insulating materials from among SiOₓ, SiNₓ, SiOₓN_{y}, Al₂O₃, TiO₂, Ta₂O₅, HfO₂, and ZnOₓ and may be formed by chemical vapor deposition (“CVD”), etc. ZnOₓ may include ZnO and/or ZnO₂.

According to an embodiment, as illustrated in FIG. 5, the encapsulation layer 40 may be arranged on the display portion DP and the connection portion CP. The encapsulation layer 40 may include one inorganic layer. In this case, the inorganic layer may include a single layer or multiple layers. Alternatively, the encapsulation layer 40 may include a first inorganic layer and a second inorganic layer. Alternatively, the encapsulation layer 40 may include a first inorganic layer, a second inorganic layer, and an organic layer arranged therebetween. When the encapsulation layer 40 includes the organic layer, the organic layer may be arranged only on the display portion DP and may not be arranged on the connection portion CP. That is, only the first inorganic layer and the second inorganic layer may be arranged on the connection portion CP.

The optical functional layer 50 may be arranged on the encapsulation layer 40. The optical functional layer 50 may include a reflection prevention layer. The reflection prevention layer may reduce reflectivity of light (external light) incident toward the display apparatus 1 from the outside. According to an embodiment, the optical functional layer 50 may include a polarization film. Alternatively, the optical functional layer 50 may include a filter plate including a black matrix and color filters.

Although not illustrated in FIG. 5, a touch screen layer may be arranged between the encapsulation layer 40 and the optical functional layer 50. The touch screen layer may obtain coordinate information according to an external input, for example, a touch event. The touch screen layer may include a touch electrode and touch lines connected to the touch electrode. The touch screen layer may detect the external input based on a magnetic capacitance method or a mutual capacitance method.

The cover window 60 may be arranged on the optical functional layer 50. The cover window 60 may protect the display panel 10.

As illustrated in FIG. 6, when an external force is applied to the display apparatus 1 (for example, when the external force is applied to the flexible substrate 30), shapes and/or positions of one or more members of the display apparatus 1 may be changed. For example, when pressure is applied to the flexible substrate 30, a distance between the display portions DP of the display panel 10 or a distance d between the pillar layers 20 may be reduced. Also, the connection portion CP of the display panel 10 may be bent. At least a portion of the encapsulation layer 40, at least a portion of the optical functional layer 50, and/or at least a portion of the cover window 60 may be bent.

As described above, when an external force is applied to the display apparatus 1, the distance between the display portions DP of the display panel 10 or the distance d between the pillar layers 20 may be changed, and shapes of the display portions DP of the display panel 10 and a shape of each of the pillar layers 20 may not be changed. Thus, because the shapes of the display portions DP and the pillar layers 20 may not be changed, the pixels PX1 and PX2 arranged in the display portion DP may be protected. While the pixels PX1 and PX2 are protected, the display apparatus 1 may be changed into various shapes.

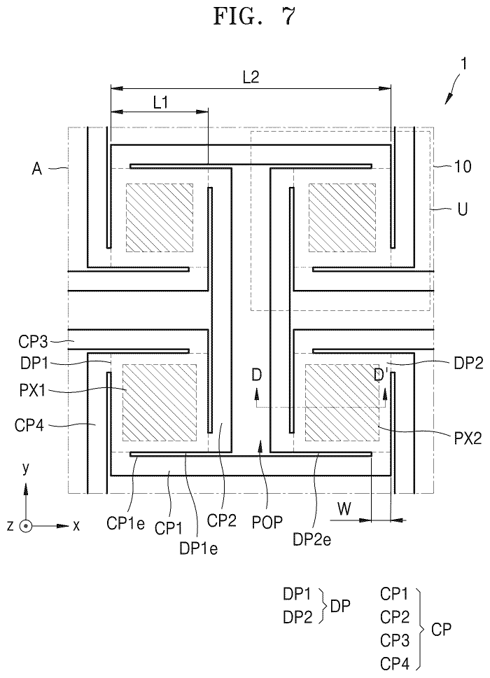

FIG. 7 is a schematic plan view of the display apparatus 1 according to an embodiment. FIG. 7 illustrates a modified embodiment of FIG. 4 and is an enlarged view of region A of FIG. 2.

Referring to FIG. 7, the display panel 10 included in the display apparatus 1 may include the display portion DP and the connection portion CP. The display portion DP may include the first display portion DP1 and the second display portion DP2. The first pixel PX1 may be arranged in the first display portion DP1, and the second pixel PX2 may be arranged in the second display portion DP2. The connection portion CP may include a first connection portion CP1, a second connection portion CP2, a third connection portion CP3, and a fourth connection portion CP4.

The plurality of display portions DP may be apart from each other in the first direction (for example, the +x direction or the −x direction) and/or the second direction (for example, the +y direction or the −y direction). For example, the first display portion DP1 and the second display portion DP2 may be apart from each other in the first direction (for example, the +x direction or the −x direction) and/or the second direction (for example, the +y direction or the −y direction).

The connection portion CP may extend between the display portions DP adjacent to each other. According to an embodiment, each display portion DP may be connected to four connection portions CP. The four connection portions CP connected to one display portion DP may extend in different directions from each other, and each connection portion CP may be connected to another display portion DP adjacent to the one display portion DP described above.

According to an embodiment, the first connection portion CP1 may extend from the first display portion DP1 to the second display portion DP2. Thus, the first display portion DP1 may be connected with the second display portion DP2 by the first connection portion CP1, and the first display portion DP1, the second display portion DP2, and the first connection portion CP1 may be integrally provided.

The penetration-opening portion POP may be defined in the display panel 10. The first display portion DP1 and the second display portion DP2 may be apart from each other with the penetration-opening portion POP therebetween. The penetration-opening portion POP may penetrate through the display panel 10. Thus, components of the display panel 10 may not be arranged in the penetration-opening portion POP.

According to an embodiment, at least a portion of the penetration-opening portion POP may be defined by edges of the display portions DP and edges of the connection portions CP. For example, at least a portion of the penetration-opening portion POP may be defined by the edge DP1e of the first display portion DP1, the edge DP2e of the second display portion DP2, and an edge CP1e of the first connection portion CP1.

One display portion DP and some of the connection portions CP extending from the one display portion DP may be defined as one basic unit U. The basic unit U may be repeatedly arranged in the first direction (for example, the +x direction or the −x direction) and the second direction (for example, the +y direction or the −y direction), and it may be understood that the display panel 10 (FIG. 2) may include the repeatedly arranged basic units U that are connected to each other. Two basic units U that are adjacent to each other may be symmetrical with each other. For example, in FIG. 7, two basic units U adjacent to each other in right and left directions may be symmetrical with each other in the right and left directions based on a symmetrical axis that is between the two basic units U and parallel with the second direction (for example, the +y direction or the −y direction). Similarly, in FIG. 7, two basic units U adjacent to each other in upper and lower directions may be symmetrical with each other in the upper and lower directions based on a symmetrical axis that is between the two basic units U and parallel with the first direction (for example, the +x direction or the −x direction).

According to an embodiment, a ratio between a length L1 of the display portion DP and a length L2 of the connection portion CP in the first direction (for example, the +x direction or the −x direction) may be 100:1 to 1:100. Also, the ratio between the length L1 of the display portion DP and the length L2 of the connection portion CP in the first direction (for example, the +x direction or the −x direction) and a ratio between the length L1 of the display portion DP and the length L2 of the connection portion CP in the second direction (for example, the +y direction or the −y direction) may be the same as each other. However, the disclosure is not limited thereto. Also, the ratio between the length L1 of the display portion DP and the length L2 of the connection portion CP in the first direction (for example, the +x direction or the −x direction) and the ratio between the length L1 of the display portion DP and the length L2 of the connection portion CP in the second direction (for example, the +y direction or the −y direction) may be different from each other.

According to an embodiment, when a width W of a connection region at which the connection portion CP and the display portion DP are connected with each other is less than about 1 μm, the width W of the connection position is so small that a portion of a line WL (see FIG. 8) arranged in the connection portion CP may be exposed, a width of the line WL may be reduced, so that the conductivity may be decreased, and the line WL may be disconnected. Thus, the width W of the connection region at which the connection portion CP and the display portion DP are connected with each other may be provided to be greater than or equal to about 1 μm.

As described above, each of the first pixel PX1 and the second pixel PX2 may include the red sub-pixel Pr, the blue sub-pixel Pb, and the green sub-pixel Pg. The red sub-pixel Pr, the blue sub-pixel Pb, and the green sub-pixel Pg may emit red light, blue light, and green light, respectively. Alternatively, each of the first pixel PX1 and the second pixel PX2 may include the red sub-pixel Pr, the blue sub-pixel Pb, the green sub-pixel Pg, and the white sub-pixel. The red sub-pixel Pr, the blue sub-pixel Pb, the green sub-pixel Pg, and the white sub-pixel may emit red light, blue light, green light, and white light, respectively.

FIG. 8 is a schematic cross-sectional view of a display apparatus according to an embodiment. FIG. 8 is the cross-sectional view of the display apparatus taken along line D-D′ of FIG. 7.

Referring to FIG. 8, the display panel 10 may include the display portion DP and the connection portion CP. Also, the penetration-opening portion POP may be defined in the display panel 10.

The display panel 10 may include the substrate layer 100. The substrate layer 100 may include polymer resins, such as polyethersulfone, polyarylate, polyetherimide, polyethylene naphthalate, polyethylene terephthalate, polyphenylene sulfide, polyimide, polycarbonate, cellulose tri acetate, or cellulose acetate propionate.

According to an embodiment, the substrate layer 100 may be provided as a single-layer structure. For example, the substrate layer 100 may be provided as the single-layer structure and may be provided to be thin. Because the substrate layer 100 may be provided to be thin, the flexibility of the display apparatus 1 including the substrate layer 100 may be improved.

A buffer layer 110 may be arranged on the substrate layer 100 of the display portion DP. The buffer layer 110 may not be arranged in the connection portion CP and may be arranged only in the display portion DP. The buffer layer 110 may include an inorganic insulating material, such as SiNₓ, SiON, and SiO₂, and may include a single layer or multiple layers including the inorganic insulating material described above.

According to an embodiment, the buffer layer 110 may include an end (for example, a first tip PT1) protruding toward the penetration-opening portion POP (or protruding toward the connection portion CP).

The pixel circuit PC may be arranged in the display portion DP. The pixel circuit PC may include a thin-film transistor TFT and a storage capacitor Cst. FIG. 8 illustrates that the pixel circuit PC includes one thin-film transistor TFT and one storage capacitor Cst. However, the disclosure is not limited thereto. The pixel circuit PC may include a plurality of thin-film transistors and a plurality of storage capacitors.

An inorganic insulating layer IIL and an organic insulating layer OIL may be arranged on the substrate layer 100 of the display portion DP. The inorganic insulating layer IIL may include a first insulating layer 111, a second insulating layer 113, and a third insulating layer 115. The organic insulating layer OIL may include a first organic insulating layer 123 and a second organic insulating layer 125.

The thin-film transistor TFT and the storage capacitor Cst may be arranged on the buffer layer 110. The thin-film transistor TFT may include a semiconductor layer Act, a gate electrode GE, a source electrode SE, and a drain electrode DE. The storage capacitor Cst may include a lower electrode CE1 and an upper electrode CE2.

The semiconductor layer Act may be arranged on the buffer layer 110. The semiconductor layer Act may include polysilicon. Alternatively, the semiconductor layer Act may include amorphous silicon, an oxide semiconductor, or an organic semiconductor. The semiconductor layer Act may include a channel area, a drain area and a source area arranged at both sides of the channel area, respectively.

The gate electrode GE may be arranged on the semiconductor layer Act. The gate electrode GE may overlap the channel area arranged therebelow. The gate electrode GE may include a low-resistance metal material. The gate electrode GE may include a conductive material including Mo, Al, Cu, Ti, etc. and may include multiple layers or a single layer including the conductive material described above.

The first insulating layer 111 may be arranged between the semiconductor layer Act and the gate electrode GE. The first insulating layer 111 may include an inorganic insulating material, such as SiO₂, SiNₓ, SiON, Al₂O₃, TiO₂, Ta₂O₅, HfO₂, or ZnO. ZnOₓ may include ZnO and/or ZnO₂.

The second insulating layer 113 may be provided to cover the gate electrode GE. Similarly to the first insulating layer 111, the second insulating layer 113 may include an inorganic insulating material, such as SiO₂, SiNₓ, SiON, Al₂O₃, TiO₂, Ta₂O₅, HfO₂, and/or ZnO.

The upper electrode CE2 of the storage capacitor Cst may be arranged on the second insulating layer 113. The upper electrode CE2 may overlap the gate electrode GE arranged therebelow. Here, the gate electrode GE and the upper electrode CE2 overlapping each other with the second insulating layer 113 therebetween may form the storage capacitor Cst. That is, the gate electrode GE of the thin-film transistor TFT may function as the lower electrode CE1 of the storage capacitor Cst.

As described above, the storage capacitor Cst and the thin-film transistor TFT may overlap each other. However, the disclosure is not limited thereto. The storage capacitor Cst may not overlap the thin-film transistor TFT.

The upper electrode CE2 may include Al, Pt, Pd, Ag, Mg, Au, Ni, Nd, Ir, Cr, Ca, Mo, Ti, W, and/or Cu and may include a single layer or multiple layers including the material described above.

The third insulating layer 115 may cover the upper electrode CE2. The third insulating layer 115 may include SiO₂, SiNₓ, SiON, Al₂O₃, TiO₂, Ta₂O₅, HfO₂, or ZnO. The third insulating layer 115 may include a single layer or multiple layers including the inorganic insulating material described above.

Each of the drain electrode DE and the source electrode SE may be arranged on the third insulating layer 115. The drain electrode DE and the source electrode SE may include a highly conductive material. The drain electrode DE and the source electrode SE may include a conductive material including Mo, Al, Cu, Ti, etc. and may include multiple layers or a single layer including the material described above. According to an embodiment, the drain electrode DE and the source electrode SE may have a multi-layered structure of Ti/Al/Ti.

The first organic insulating layer 123 may be arranged to cover the drain electrode DE and the source electrode SE. The first organic insulating layer 123 may include an organic material. For example, the first organic insulating layer 123 may include an organic insulating material, such as a general-purpose polymer such as polymethylmethacrylate (“PMMA”) or polystyrene (“PS”), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The second organic insulating layer 125 may include an organic material. The second organic insulating layer 125 may include an organic insulating material, such as a general-purpose polymer such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

According to an embodiment, a passivation layer 130 may be arranged on the second organic insulating layer 125. The passivation layer 130 may be a single layer or multiple layers including an inorganic material such as SiNₓ and/or SiO₂ to function as an insulating layer.

The passivation layer 130 may be arranged between an organic light-emitting diode OLED and the second organic insulating layer 125. A first electrode 210 of the organic light-emitting diode OLED may be arranged on the passivation layer 130.

According to an embodiment, the passivation layer 130 may include an end (for example, a second tip PT2) protruding toward the penetration-opening portion POP (or protruding toward the connection portion CP).

The organic light-emitting diode OLED may be arranged on the passivation layer 130. The organic light-emitting diode OLED may include the first electrode 210, an emission layer 220, and a second electrode 230.

The first electrode 210 may be arranged on the passivation layer 130. The first electrode 210 may be electrically connected to a contact metal CM arranged on the first organic insulating layer 123. Also, the contact metal CM may be electrically connected to the drain electrode DE or the source electrode SE. Thus, the organic light-emitting diode OLED may be electrically connected to the pixel circuit PC.

The first electrode 210 may include conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). Alternatively, the first electrode 210 may include a reflective layer including Ag, Mg, Al, Pt, Pd, Au, Ni, Nd, Ir, Cr, or a compound thereof. Alternatively, the first electrode 210 may further include a layer including ITO, IZO, ZnO, or In₂O₃, above/below the reflective layer described above.

A pixel-defining layer 180 having an opening exposing at least a portion of the first electrode 210 may be arranged on the first electrode 210. The pixel-defining layer 180 may include an organic insulating material and/or an inorganic insulating material. The opening defined in the pixel-defining layer 180 may define an emission area of light emitted from the organic light-emitting diode OLED. For example, a width of the opening may correspond to a width of the emission area.

Although not shown, a spacer may be arranged on the pixel-defining layer 180. According to a method of manufacturing the display panel 10, a mask sheet may be used. Here, the mask sheet may be introduced into the opening of the pixel-defining layer 180 or may adhere to the pixel-defining layer 180. The spacer may prevent the damage or fracture defects of the substrate layer 100 and one or more layers on the substrate layer 100 caused by the mask sheet when a deposition material is deposited on the substrate layer 100.

The spacer may include an organic material, such as polyimide. Alternatively, the spacer may include an inorganic insulating material, such as SiNₓ or SiO₂, or may include an organic insulating material and an inorganic insulating material.

According to an embodiment, the spacer may include a different material from the pixel-defining layer 180. Alternatively, the spacer may include the same material as the pixel-defining layer 180, and in this case, the pixel-defining layer 180 and the spacer may be formed together in a mask process using a halftone mask, etc.

The emission layer 220 may be arranged on the first electrode 210, at least a portion of which is exposed by the pixel-defining layer 180. The emission layer 220 may be arranged in the opening defined in the pixel-defining layer 180. The emission layer 220 may include a high molecular-weight organic material or a low molecular-weight organic material emitting certain color light.

Although not shown, a first functional layer and a second functional layer may be respectively arranged below and above the emission layer 220. The first functional layer may include, for example, a hole transport layer (“HTL”), or an HTL and a hole injection layer (“HIL”). The second functional layer may be arranged above the emission layer 220 and may be optional. The second functional layer may include an electron transport layer (“ETL”) and/or an electron injection layer (“EIL”). The first functional layer and/or the second functional layer may be arranged only on the display portion DP. Alternatively, the first functional layer and/or the second functional layer may be arranged on the display portion DP and the connection portion CP.

The second electrode 230 may be arranged on the emission layer 220. The second electrode 230 may include a conductive material having a low work function. For example, the second electrode 230 may include a (semi-) transparent layer including Ag, Mg, Al, Pt, Pd, Au, Ni, Nd, Ir, Cr, Li, Ca, or an alloy thereof. Alternatively, the second electrode 230 may further include a layer, such as ITO, IZO, ZnO, or In₂O₃, on the (semi-) transparent layer including the material described above. The second electrode 230 may be arranged only in the display portion DP. Alternatively, the second electrode 230 may be arranged in the display portion DP and the connection portion CP.

According to an embodiment, a capping layer 250 may be arranged on the second electrode 230. The capping layer 250 may include an inorganic material (e.g., LiF), and/or an organic material. The capping layer 250 may be arranged only on the display portion DP. Alternatively, the capping layer 250 may be arranged on the display portion DP and the connection portion CP.

The encapsulation layer 40 may be arranged on the capping layer 250. According to an embodiment, the encapsulation layer 40 may include at least one inorganic layer. In this case, the inorganic layer may include a single layer or multiple layers. Alternatively, the encapsulation layer 40 may include a first inorganic layer and a second inorganic layer. Alternatively, the encapsulation layer 40 may include a first inorganic layer, a second inorganic layer, and an organic layer arranged therebetween. When the encapsulation layer 40 includes an organic layer, the organic layer may be arranged only on the display portion DP and may not be arranged on the connection portion CP. That is, only the first inorganic layer and the second inorganic layer may be arranged on the connection portion CP. The inorganic layer may include one or more inorganic materials from among Al₂O₃, TiO₂, Ta₂O₅, HfO₂, ZnO, SiO₂, SiNₓ, and SiON.

Although not shown, a touch screen layer may be arranged on the encapsulation layer 40, and an optical functional layer may be arranged on the touch screen layer. The touch screen layer may obtain coordinate information based on an external input, for example, a touch event. The optical functional layer may reduce a reflectivity of light (external light) incident toward a display apparatus from the outside and/or may improve a color purity of light emitted from the display apparatus. According to an embodiment, the optical functional layer may include a phase retarder and a polarizer. The phase retarder may include a film-type phase retarder or a liquid crystal coating-type phase retarder, and may include a λ/2 phase retarder and/or a λ/4 phase retarder. The polarizer may also include a film-type polarizer or a liquid crystal coating-type polarizer. The film-type polarizer may include an elongation-type synthetic resin film, and the liquid crystal coating-type polarizer may include liquid crystals arranged in a certain shape. The phase retarder and the polarizer may further include a protective film.

Alternatively, the optical functional layer may include a black matrix and color filters. The color filters may be arranged by taking into account a color of light emitted from each of pixels of the display panel 10. Each of the color filters may include a red, green, or blue pigment or dye. Alternatively, each of the color filters may further include quantum dots, in addition to the pigment or the dye described above. Alternatively, some of the color filters may not include the pigment or the dye described above and may include scattered particles, such as oxide titanium.

Alternatively, the optical functional layer may include a destructive interference structure. The destructive interference structure may include a first reflective layer and a second reflective layer disposed on different layers from each other. First reflective light and second reflective light reflected from the first reflective layer and the second reflective layer, respectively, may destructively interfere, and thus, the reflectivity of external light may be decreased.

An adhesive member may be arranged between the touch screen layer and the optical functional layer. The adhesive member may not be limited to particular types and may be implemented as general members known in the art. For example, the adhesion member may include a pressure sensitive adhesive (“PSA”).

The inorganic insulating layer IIL may have an open portion IIL-OP corresponding to the connection portion CP. The open portion IIL-OP may denote an area where the inorganic insulating layer IIL is removed. An upper surface of the substrate layer 100 (or an upper surface of the buffer layer 110) may be exposed through the open portion IIL-OP. Although the area in which the inorganic insulating layer IIL is removed is defined as the open portion IIL-OP, the inorganic insulating layer IIL remaining on a plane may have an island shape corresponding to the display portion DP. The open portion IIL-OP may extend from the connection portion CP to the display portion DP. That is, an area of the open portion IIL-OP may be the same as or greater than an area of the connection portion CP.

According to an embodiment, an organic material layer 121 may be arranged on the substrate layer 100 of the connection portion CP. The organic material layer 121 arranged in the connection portion CP may fill a step difference of the inorganic insulating layer IIL, the step difference being formed by the open portion IIL-OP. A thickness of the organic material layer 121 in a thickness direction of the display apparatus 1 may be approximately the same as a height of the step difference of the inorganic insulating layer IIL that is formed by the open portion IIL-OP. By filling the open portion IIL-OP of the inorganic insulating layer IIL with the organic material layer 121, the flexibility of the connection portion CP may be improved, and an area to arrange the line WL to be described below may be planarized as much as possible so as to increase the reliability of the line WL.

According to an embodiment, the line WL may be arranged in the connection portion CP and configured to transfer an electrical signal. According to an embodiment, the line WL may be arranged on the organic material layer 121. Although not illustrated, the line WL may be electrically connected to the pixel circuit PC. Through the line WL, the pixel circuit PC of the second display portion DP2 may be electrically connected to the pixel circuit of another display portion adjacent to the second display portion DP2 (for example, the pixel circuit of the first display portion). The line WL may include a highly conductive material. The line WL may include a conductive material including Mo, Al, Cu, Ti, etc. and may include multiple layers or a single layer including the material described above. According to an embodiment, the line WL may have a layered structure of Ti/Al/Ti. According to an embodiment, the line WL may be formed by the same process as the drain electrode DE and/or the source electrode SE of the display portion DP.

According to an embodiment, the line WL may electrically connect the display portions. For example, the line WL may include a data line, a scan line, a power supply line, etc. FIG. 8 illustrates that one line WL may be provided. However, the disclosure is not limited thereto. For example, the line WL may be provided in a plurality.

Also, FIG. 8 illustrates that the line WL may be provided between the organic material layer 121 and the first organic insulating layer 123. However, the disclosure is not limited thereto. For example, the line WL may be provided not only between the organic material layer 121 and the first organic insulating layer 123, but also between the first organic insulating layer 123 and the second organic insulating layer 125.

According to an embodiment, the penetration-opening portion POP may be defined between the display portion DP and the connection portion CP and between the connection portions CP.

According to an embodiment, a side-wall groove 107 may be provided in the substrate layer 100 of the display portion DP and/or the connection portion CP. The side-wall groove 107 of the substrate layer 100 may be defined throughout a side surface 100b and a lower surface 100a of the substrate layer 100. For example, the side-wall groove 107 of the substrate layer 100 may be formed by removing at least a portion of the lower surface 100a of the substrate layer 100 and at least a portion of the side surface 100b of the substrate layer 100 around a region in which the lower surface 100a and the side surface 100b of the substrate layer 100 meet each other. According to an embodiment, the side-wall groove 107 may be recessed from the lower surface 100a of the substrate layer 100.

According to an embodiment, at least a portion of the side-wall groove 107 may be provided along a circumference of the display portion DP. Also, at least a portion of the side-wall groove 107 may be provided along a circumference of the connection portion CP.

According to an embodiment, the encapsulation layer 40 may be arranged in at least a portion of the side-wall groove 107 (e.g., top surface of the side-wall groove 107). That is, the encapsulation layer 40 may be at least partially arranged to cover the top surface of the side-wall groove 107. According to an embodiment, the encapsulation layer 40 may further cover side surfaces of the second electrode 230, the passivation layer 130, the organic insulating layer OIL, the buffer layer 110, and the organic material layer 212.

According to an embodiment, the side-wall groove 107 may be provided to have a quadrangular, triangular, curved, or stair shape in a cross-sectional view. That is, the side-wall groove 107 may have any one of shapes for disconnecting the encapsulation layer 40 or reducing a thickness of the encapsulation layer 40. According to an embodiment, in the side-wall groove 107, the encapsulation layer 40 may be tapered to an end of the encapsulation layer 40.

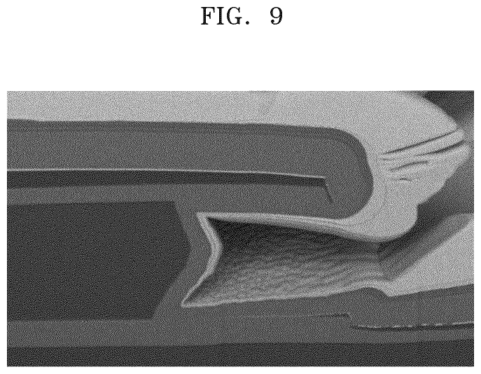

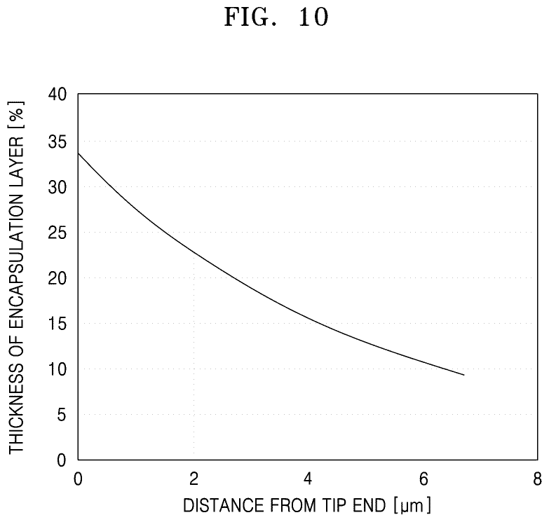

FIGS. 9 and 10 are views for describing a thickness tendency of an encapsulation layer according to a depth of a side-wall groove.

Referring to FIGS. 9 and 10, it is identified that the thickness of the encapsulation layer decreases from a tip end toward the inside of a groove portion. In detail, it is identified that when the encapsulation layer is deposited in the groove portion, the thickness of the encapsulation layer formed on a lower surface of the tip end is less than the thickness of the encapsulation layer formed on an upper surface of the tip end, that is, the thickness of the encapsulation layer decreases from the tip end toward the inside of the groove portion. For example, it is identified that while the thickness of the encapsulation layer at the tip end is about 35% of a reference thickness, the thickness of the encapsulation layer at a point of about 6 μm from the tip end in the first direction (x direction in FIG. 8) is about 10% of the reference thickness. Here, the thickness of the encapsulation layer in the graph of FIG. 10 may be a ratio of a thickness of the encapsulation layer at a certain point (e.g., a certain point on the lower surface of the tip end) to a reference thickness (e.g., a thickness of the encapsulation layer formed on the upper surface of the tip end).

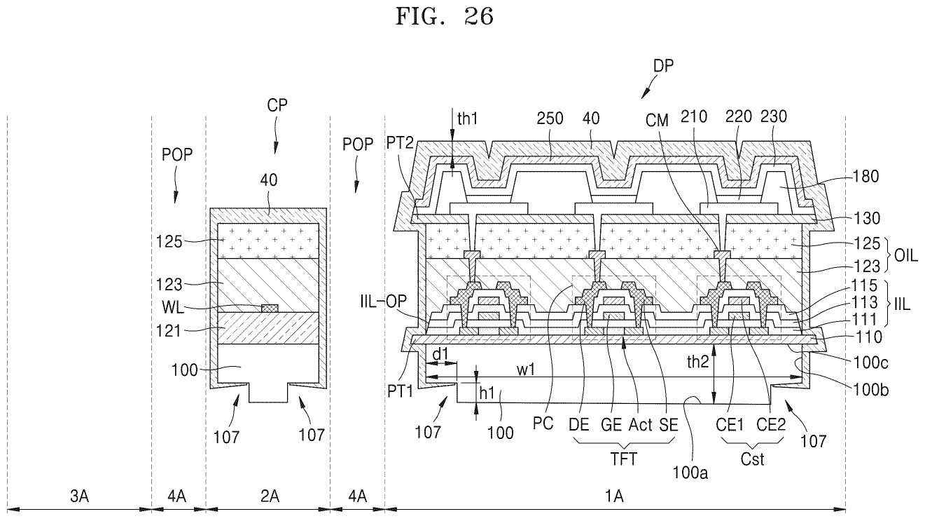

According to an embodiment, when the thickness of the encapsulation layer is about 10% of the reference thickness in the side-wall groove 107, the thickness of the encapsulation layer 40 at this point is small, and thus, failure of releasing the encapsulation layer 40 may be prevented, or the detachment of the encapsulation layer 40 from the side surface 100b of the substrate layer 100 may be prevented, in a process of releasing the substrate layer 100 from a carrier substrate SS (see FIG. 26).

Referring to FIG. 8 again, according to an embodiment, a depth d1 of the side-wall groove 107 in a side direction (i.e., a direction parallel to a major surface plane of the substrate layer 100 defined by the x direction and the y direction) may be greater than or equal to about 6 μm and less than or equal to about 25% of a reference width w1 of the substrate layer 100 in the side direction. Here, the depth d1 of the side-wall groove 107 may be a length between the side surface 100b of the substrate layer 100 and a side surface of the side-wall groove 107 formed by removing at least a portion of the substrate layer 100 in a first direction (for example, an x direction). As used herein, the reference width w1 of the substrate layer 100 may be a length of the substrate layer 100 in the first direction (for example, the x direction) and measured in a part of the substrate layer 100, in which the side-wall groove 107 is not defined. As the depth d1 of the side-wall groove 107 increases, the thickness of the encapsulation layer 40 may be reduced. When the depth d1 of the side-wall groove 107 is less than about 6 μm, the thickness of the encapsulation layer 40 in the side-wall groove 107 may not be sufficiently reduced, and thus, in the process of releasing the substrate layer 100 from the carrier substrate SS, the encapsulation layer 40 may not be released, or the encapsulation layer 40 may be detached from the side surface 100b of the substrate layer 100. However, when the substrate layer 100 supports the components arranged on the substrate layer 100, and when the depth d1 of the side-wall groove 107 is greater than about 25% of the reference width w1 of the substrate layer 100, the ratio of the side-wall groove 107 in the substrate layer 100 may be too high, and thus, the substrate layer 100 may not support the components arranged on the substrate layer 100. That is, mechanical stability of the substrate layer 100 may not be obtained. Thus, when the depth d1 of the side-wall groove 107 is greater than or equal to about 6 μm and less than or equal to about 25% of the reference width w1 of the substrate layer 100, the thickness of the encapsulation layer 40 may be reduced to about 10%, so that disconnection of the encapsulation layer 40 or thinness of the encapsulation layer 40 may be induced, in order to easily release the substrate layer 100 from the carrier substrate SS and obtain mechanical stability of the substrate layer 100.

According to an embodiment, a height h1 of the side-wall groove 107 may be greater than or equal to about 150% of a reference thickness th1 of the encapsulation layer 40 and less than or equal to about 50% of a reference thickness th2 of the substrate layer 100. Here, the height h1 of the side-wall groove 107 may be a length between the lower surface 100a of the substrate layer 100 and an upper surface of the side-wall groove 107 formed by removing at least a portion of the substrate layer 100 in a thickness direction (i.e., z direction) of the display apparatus 1. For example, the height h1 of the side-wall groove 107 may be a length in a third direction (for example, a z direction) crossing the first direction (for example, the x direction). As used herein, the reference thickness th1 of the encapsulation layer 40 may denote a thickness from a lower surface to an upper surface of the encapsulation layer 40 arranged on a flat surface of the capping layer 250. As used herein, the reference thickness th2 of the substrate layer 100 may be a thickness from the lower surface 100a of the substrate layer 100 to an upper surface 100c of the substrate layer 100. According to the disclosure, the side-wall groove 107 may be defined in the substrate layer 100, and thus, disconnection of the encapsulation layer 40 or a small thickness of the encapsulation layer 40 may be induced through the side-wall groove 107, and thus, failure of releasing the encapsulation layer 40 may be effectively prevented, or the detachment of the encapsulation layer 40 from the side surface 100b of the substrate layer 100 may be effectively prevented, in a process of releasing the substrate layer 100 from the carrier substrate SS. However, when the height h1 of the side-wall groove 107 is less than about 150% of the reference thickness th1 of the encapsulation layer 40, the height of the side-wall groove 107 may be too little, and thus, the encapsulation layer 40 arranged in the side-wall groove 107 and the encapsulation layer 40 formed on the carrier substrate SS may be connected with each other, so that the encapsulation layer 40 may not be released, or the encapsulation layer 40 arranged on the side surface 100b of the substrate layer 100 may be detached, in the process of releasing the substrate layer 100 from the carrier substrate SS. However, when the height h1 of the side-wall groove 107 is greater than about 50% of the reference thickness th2 of the substrate layer 100, the ratio of the side-wall groove 107 in the substrate layer 100 may be too high, and thus, the substrate layer 100 may not support the components arranged on the substrate layer 100. That is, mechanical stability of the substrate layer 100 may not be obtained. Thus, when the height h1 of the side-wall groove 107 is greater than or equal to about 150% of the reference thickness th1 of the encapsulation layer 40 and less than or equal to about 50% of the reference thickness th2 of the substrate layer 100, disconnection of the encapsulation layer 40 or a small thickness of the encapsulation layer 40 may be induced, so as to easily release the substrate layer 100 from the carrier substrate SS, and obtain mechanical stability of the substrate layer 100.

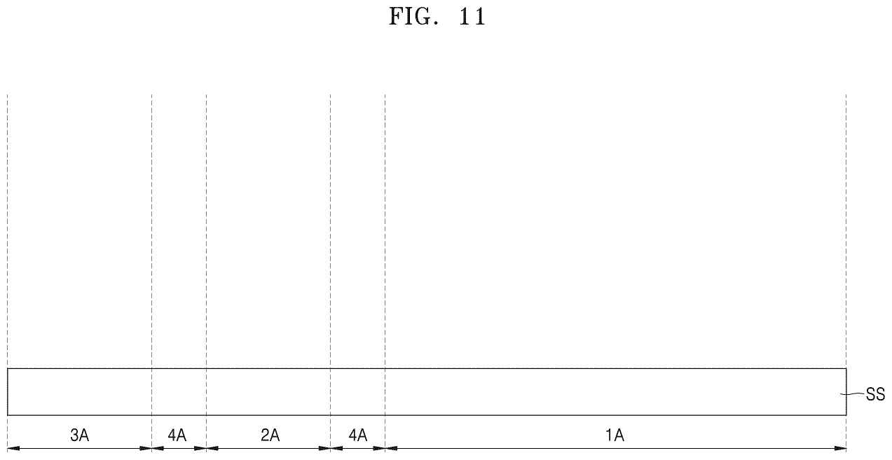

FIGS. 11 to 28 are schematic views for describing a method of manufacturing a display apparatus, according to an embodiment.

Hereinafter, the method of manufacturing the display apparatus is described with reference to FIGS. 11 to 28.

Referring to FIG. 11, the carrier substrate SS may include a display area 1A, a connection area 2A, a dummy area 3A, and a cut area 4A. When manufacturing a flexible display apparatus, a bendable display apparatus, etc., it is required to form the substrate layer 100 having a flexible property or a bendable property. In order to form this substrate layer 100, the carrier substrate SS may be used. The carrier substrate SS may support the substrate layer 100 from below the substrate layer 100, in the process of manufacturing the display apparatus. To this end, the carrier substrate SS may have to have a rigid property. Thus, the carrier substrate SS may include glass. In detail, the carrier substrate SS may include glass including SiOₓ. However, the carrier substrate SS may further include a small amount of impurities. For example, the impurities may include Al, K, or Na.

The display area 1A of the carrier substrate SS may correspond to the display portion DP (see FIG. 1) of the display panel 10 (or the substrate layer 100) described above. That is, components formed in the display area 1A of the carrier substrate SS may form the display portion DP of the display panel 10. However, the carrier substrate SS may be removed.

The connection area 2A of the carrier substrate SS may correspond to the connection portion CP (see FIG. 1) of the display panel 10 (or the substrate layer 100) described above. That is, components formed in the connection area 2A of the carrier substrate SS may form the connection portion CP of the display panel 10. However, the carrier substrate SS may be removed.

The dummy area 3A and the cut area 4A of the carrier substrate SS may correspond to the penetration-opening portion POP (see FIG. 1) of the display panel 10 (or the substrate layer 100) described above. That is, components formed in the dummy area 3A and the cut area 4A of the carrier substrate SS may be removed to form the penetration-opening portion POP of the display panel 10.

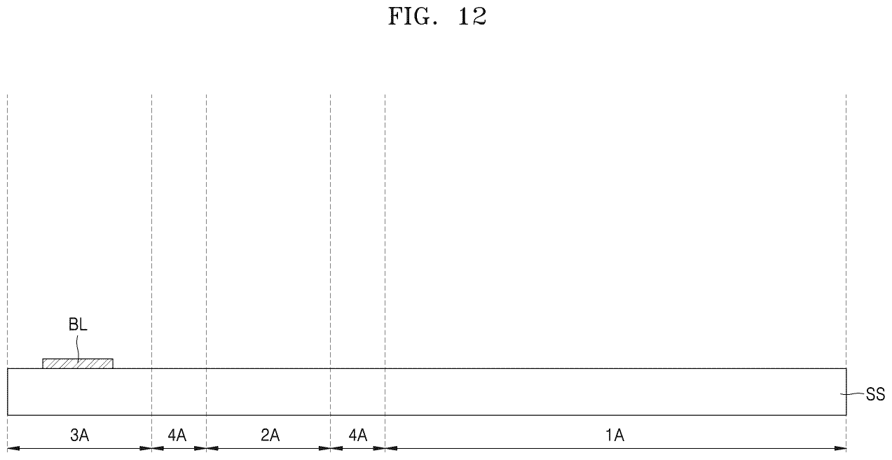

Referring to FIG. 12, a blocking layer BL may be formed in the dummy area 3A of the carrier substrate SS. The blocking layer BL may include a material for blocking (or shielding) a laser beam used in a subsequently described process of releasing the substrate layer 100. According to an embodiment, the blocking layer BL may include at least one of amorphous silicon (a-Si), poly-Si, crystalline-Si, ZnO, and IZO.

The dummy area 3A where the blocking layer BL may be formed may be removed in a subsequent process. In other words, an area in which the blocking layer BL is formed may be understood to be where the substrate layer 100 of the display apparatus is not formed.

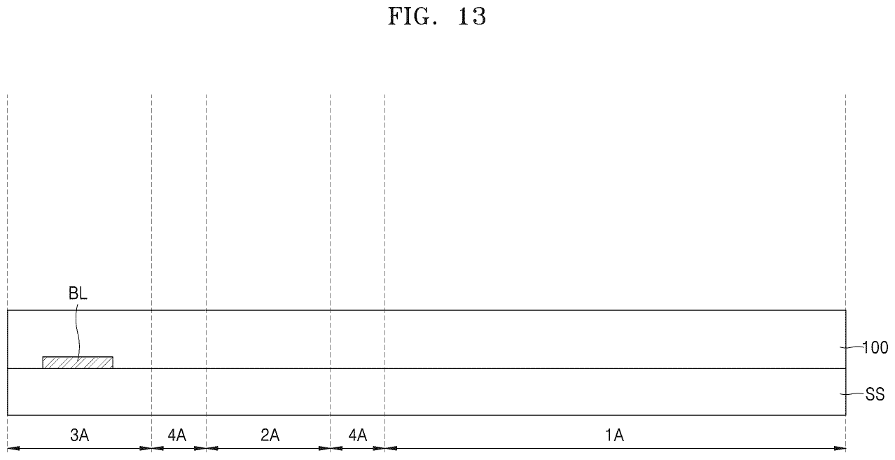

Referring to FIG. 13, after forming the blocking layer BL in the dummy area 3A, the substrate layer 100 may be formed throughout the display area 1A, the connection area 2A, the dummy area 3A, and the cut area 4A. The substrate layer 100 may include polymer resins.

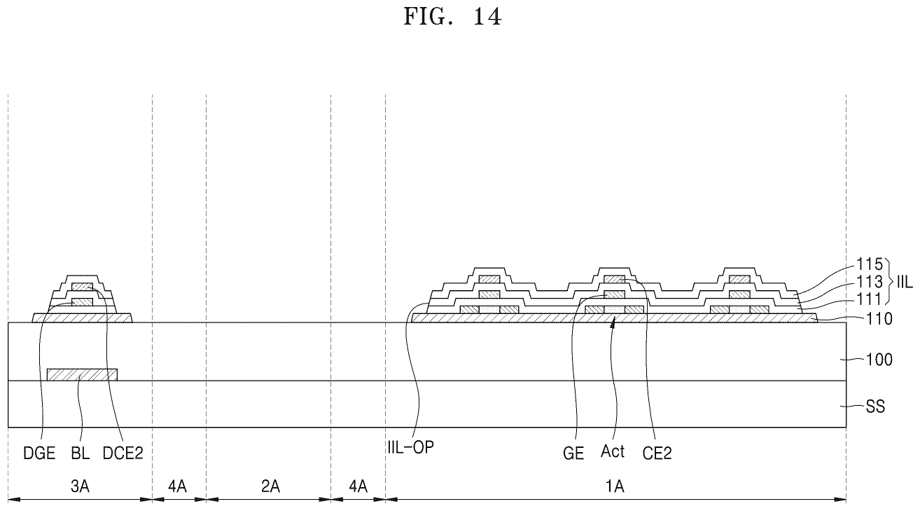

Referring to FIG. 14, the buffer layer 110 may be formed on the substrate layer 100 in the display area 1A and the dummy area 3A. The semiconductor layer Act may be formed on the buffer layer 110 in the display area 1A. Also, the first insulating layer 111 may be formed on the semiconductor layer Act in the display area 1A and on the buffer layer 110 in the dummy area 3A.

Also, the gate electrode GE may be formed on the first insulating layer 111 in the display area 1A, and a dummy gate electrode DGE may be formed on the first insulating layer 111 in the dummy area 3A. Also, the second insulating layer 113 may be formed on the gate electrode GE and the dummy gate electrode DGE. According to an embodiment, the gate electrode GE and the dummy gate electrode DGE may be provided on the same layer by including the same material as each other.

The upper electrode CE2 may be formed on the second insulating layer 113 in the display area 1A, and a dummy upper electrode DCE2 may be formed on the second insulating layer 113 in the dummy area 3A. Also, the third insulating layer 115 may be formed on the upper electrode CE2 and the dummy upper electrode DCE2. According to an embodiment, the upper electrode CE2 and the dummy upper electrode DCE2 may be provided on the same layer by including the same material as each other.

As described above with reference to FIG. 8, the first insulating layer 111, the second insulating layer 113, and the third insulating layer 115 may form the inorganic insulating layer IIL. That is, the inorganic insulating layer IIL may include the first insulating layer 111, the second insulating layer 113, and the third insulating layer 115. Also, the inorganic insulating layer IIL may have the open portion IIL-OP corresponding to the connection area 2A. The open portion IIL-OP may denote an area in which the inorganic insulating layer IIL is removed. An upper surface of the substrate layer 100 may be exposed through the open portion IIL-OP.

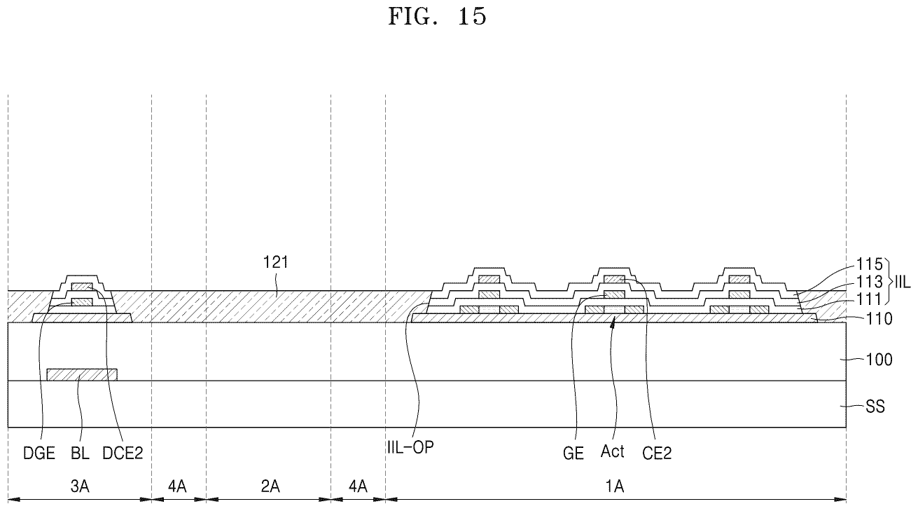

Referring to FIG. 15, the organic material layer 121 may be formed on a region other than a region in which the inorganic insulating layer IIL is formed. The organic material layer 121 may be formed in the connection area 2A and the cut area 4A. Also, the organic material layer 121 may also be formed in a portion of the display area 1A and a portion of the dummy area 3A. The organic material layer 121 may fill a step difference of the inorganic insulating layer IIL, the step difference being formed by the open portion IIL-OP.

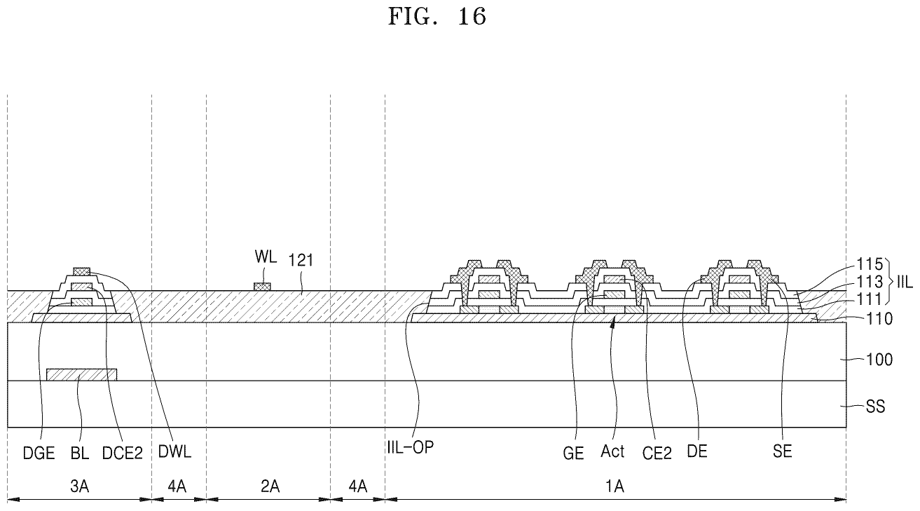

Referring to FIG. 16, the drain electrode DE and/or the source electrode SE may be formed in the display area 1A. Also, the line WL may be formed in the connection area 2A, and the dummy line DWL may be formed in the dummy area 3A. The drain electrode DE, the source electrode SE, the line WL, and the dummy line DWL may be formed by the same process.

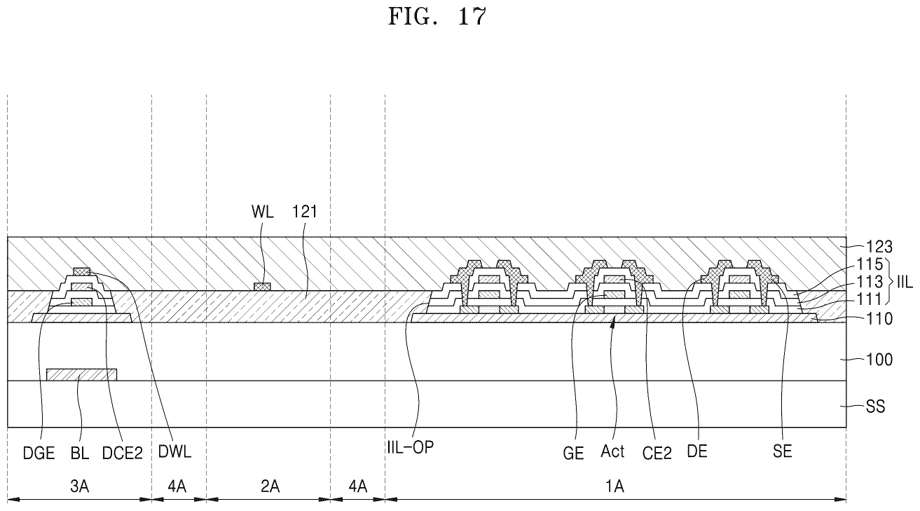

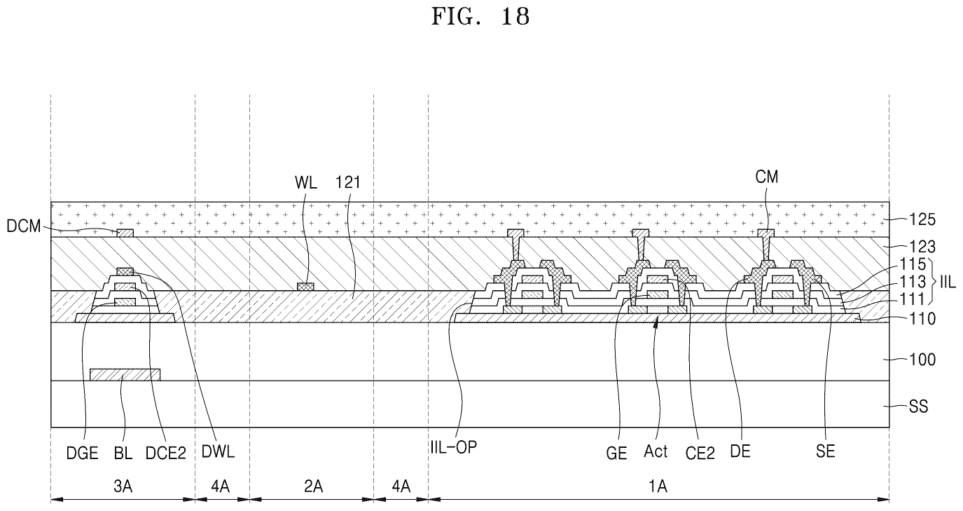

Referring to FIG. 17, the first organic insulating layer 123 may be formed throughout the display area 1A, the connection area 2A, the dummy area 3A, and the cut area 4A. Also, referring to FIG. 18, the contact metal CM may be formed on the first organic insulating layer 123 in the display area 1A, and a dummy contact metal DCM may be formed on the first organic insulating layer 123 in the dummy area 3A. The contact metal CM and the dummy contact metal DCM may be formed by the same process. Thereafter, the second organic insulating layer 125 may be formed throughout the display area 1A, the connection area 2A, the dummy area 3A, and the cut area 4A. Although not shown, a protection layer may be formed on the dummy contact metal DCM in the dummy area 3A.

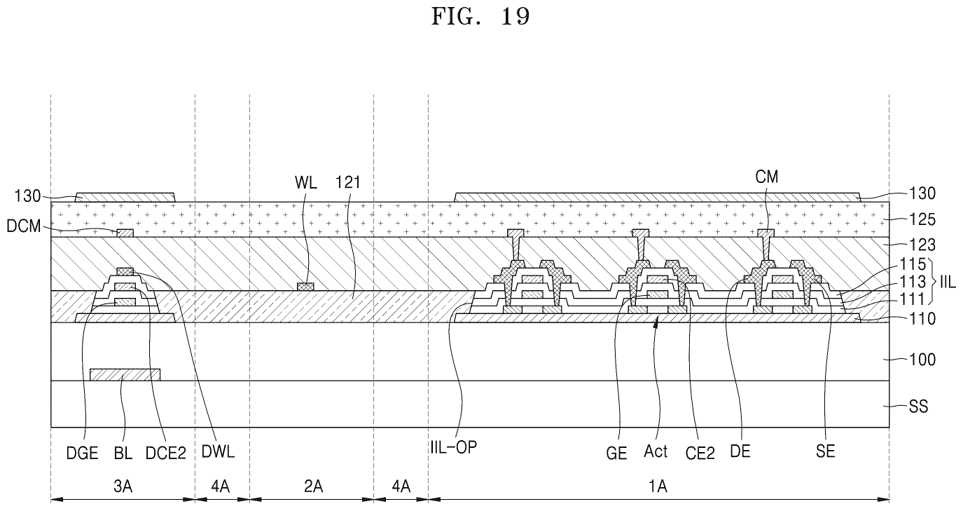

Referring to FIG. 19, the passivation layer 130 may be formed on the second organic insulating layer 125 in the display area 1A and the dummy area 3A. The passivation layer 130 may be a single layer or multiple layers including an inorganic material such as SiNₓ and/or SiO₂.

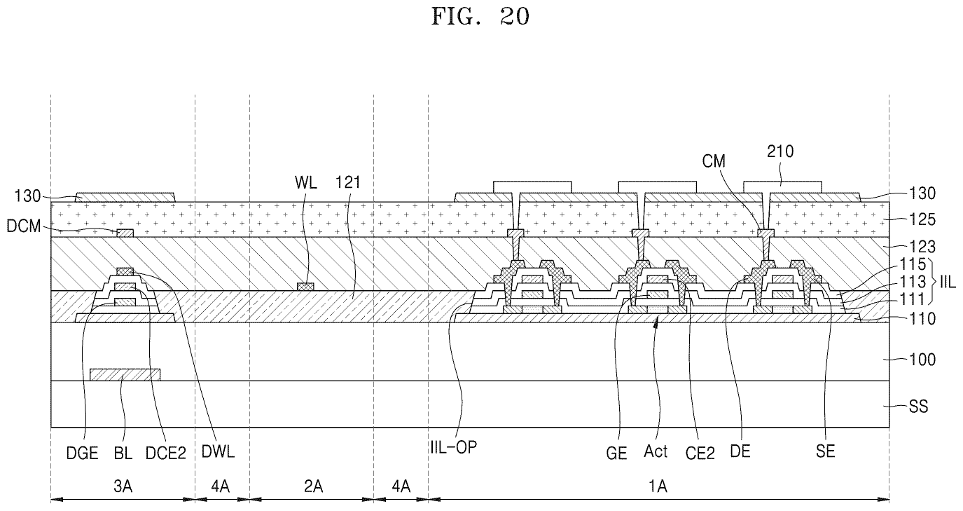

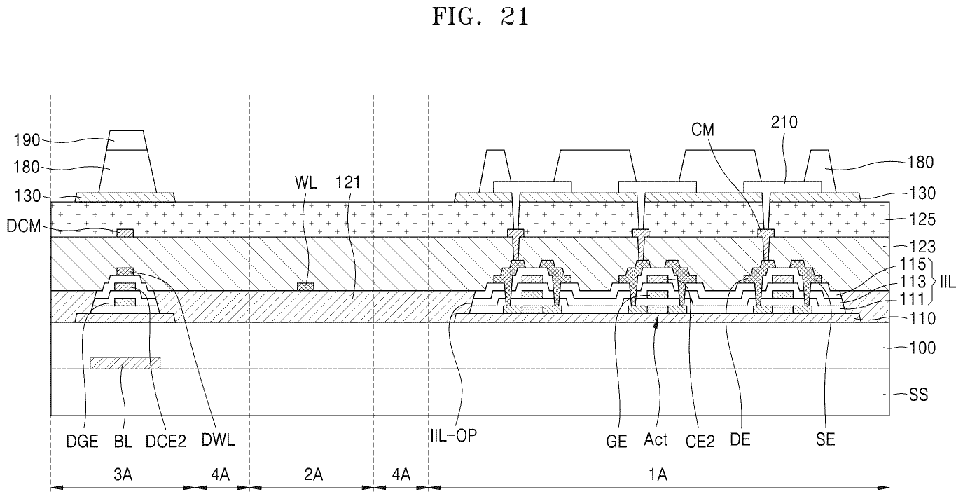

Referring to FIG. 20, the first electrode 210 may be formed on the passivation layer 130 in the display area 1A, and referring to FIG. 21, the pixel-defining layer 180 may be formed in the display area 1A and the dummy area 3A. The pixel-defining layer 180 formed in the display area 1A may expose at least a portion of the first electrode 210. Also, the spacer 190 may be formed on the pixel-defining layer 180 in the dummy area 3A. Although not shown, the spacer 190 may also be formed on the pixel-defining layer 180 in the display area 1A.

The spacer 190 may include an organic material, such as polyimide. Alternatively, the spacer 190 may include an inorganic insulating material, such as SiNₓ or SiO₂, or may include an organic insulating material and an inorganic insulating material.

According to an embodiment, the spacer 190 may include a different material from the pixel-defining layer 180. Alternatively, the spacer 190 may include the same material as the pixel-defining layer 180, and in this case, the pixel-defining layer 180 and the spacer 190 may be formed together in a mask process using a halftone mask, etc.

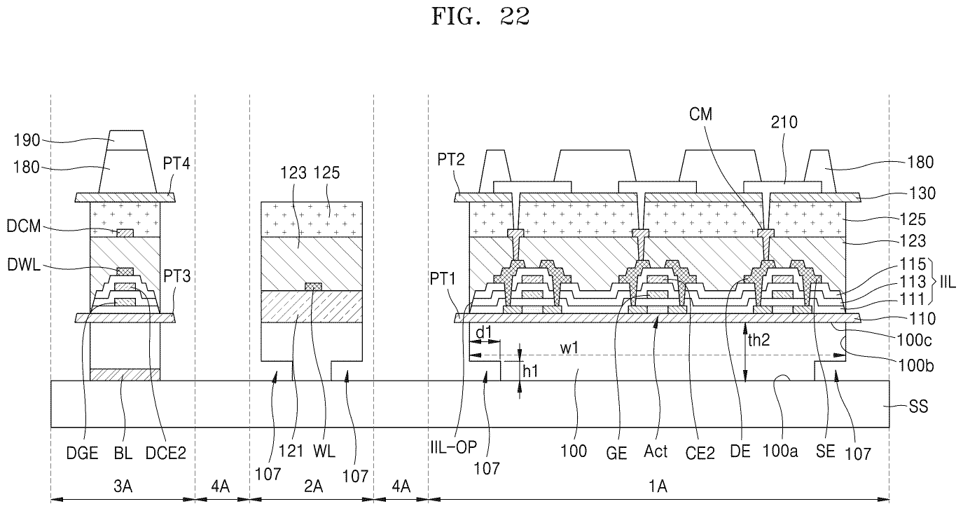

Referring to FIG. 22, at least portions of the substrate layer 100, the organic material layer 121, the first organic insulating layer 123, and the second organic insulating layer 125 overlapping the cut area 4A may be removed. In other words, at least portions of the substrate layer 100, the organic material layer 121, the first organic insulating layer 123, and the second organic insulating layer 125 in the cut area 4A may be removed. The at least the portions of the substrate layer 100, the organic material layer 121, the first organic insulating layer 123, and the second organic insulating layer 125 may be removed by a dry etching process. Thus, the carrier substrate SS in the cut area 4A may be exposed.

Also, at least portions of the substrate layer 100, the organic material layer 121, the first organic insulating layer 123, and the second organic insulating layer 125 overlapping the display area 1A, the connection area 2A, and the dummy area 3A may also be removed. In other words, at least portions of the substrate layer 100, the organic material layer 121, the first organic insulating layer 123, and the second organic insulating layer 125 in the display area 1A, the connection area 2A, and the dummy area 3A may also be removed. The at least the portions of the substrate layer 100, the organic material layer 121, the first organic insulating layer 123, and the second organic insulating layer 125 may be removed by a dry etching process.

According to an embodiment, by removing at least portions of the substrate layer 100, the organic material layer 121, the first organic insulating layer 123, and the second organic insulating layer 125 in the display area 1A (or the cut area 4A), an end (for example, a first tip PT1) protruding toward the cut area 4A may be formed in the buffer layer 110 in the display area 1A. Also, by removing at least portions of the substrate layer 100, the organic material layer 121, the first organic insulating layer 123, and the second organic insulating layer 125 in the display area 1A (or the cut area 4A), an end (for example, a second tip PT2) protruding toward the cut area 4A may be formed in the passivation layer 130 in the display area 1A.

Also, by removing at least portions of the substrate layer 100, the organic material layer 121, the first organic insulating layer 123, and the second organic insulating layer 125 in the dummy area 3A (or the cut area 4A), an end (for example, a third tip PT3) protruding toward the cut area 4A may be formed in the buffer layer 110 in the dummy area 3A. Also, by removing at least portions of the substrate layer 100, the organic material layer 121, the first organic insulating layer 123, and the second organic insulating layer 125 in the dummy area 3A (or the cut area 4A), an end (for example, a fourth tip PT4) protruding toward the cut area 4A may be formed in the passivation layer 130 in the dummy area 3A.

According to an embodiment, by removing at least portions of the substrate layer 100, the organic material layer 121, the first organic insulating layer 123, and the second organic insulating layer 125 in the display area 1A (or the cut area 4A), the side-wall groove 107 may be formed in the substrate layer 100 in the display area 1A. Also, by removing at least portions of the substrate layer 100, the organic material layer 121, the first organic insulating layer 123, and the second organic insulating layer 125 in the connection area 2A (or the cut area 4A), the side-wall groove 107 may be formed in the substrate layer 100 in the connection area 2A.

According to an embodiment, the side-wall groove 107 may be formed by removing at least a portion of the substrate layer 100 in the display area 1A and/or the connection area 2A, and thus, the side-wall groove 107 may be defined throughout the lower surface 100a and the side surface 100b of the substrate layer 100. For example, the side-wall groove 107 of the substrate layer 100 may be formed by removing at least a portion of the lower surface 100a of the substrate layer 100 and at least a portion of the side surface 100b of the substrate layer 100 around a region in which the lower surface 100a and the side surface 100b of the substrate layer 100 meet each other.

According to an embodiment, in a process of removing the substrate layer 100, the organic material layer 121, the first organic insulating layer 123, and the second organic insulating layer 125 through a dry etching process, over etching may be induced to form the side-wall groove 107 in at least a portion of the substrate layer 100. For example, by inducing over etching to remove at least a portion of the substrate layer 100, in the process of removing the substrate layer 100, the organic material layer 121, the first organic insulating layer 123, and the second organic insulating layer 125 through the dry etching process, the side-wall groove 107 may be formed in at least a portion of the substrate layer 100.

According to an embodiment, the side-wall groove 107 may overlap the display area 1A in a plan view, and at least a portion of the side-wall groove 107 may be provided along a circumference of the display area 1A. Also, the side-wall groove 107 may overlap the connection area 2A in a plan view, and at least a portion of the side-wall groove 107 may be provided along a circumference of the connection area 2A. As described below, the encapsulation layer 40 may be formed in the side-wall groove 107.

According to an embodiment, a depth d1 of the side-wall groove 107 may be greater than or equal to about 6 μm and less than or equal to about 25% of a reference width w1 of the substrate layer 100. Here, the depth d1 of the side-wall groove 107 may be a length between the side surface 100b of the substrate layer 100 and the side-wall groove 107 formed by removing at least a portion of the substrate layer 100 in a first direction (for example, an x direction). Also, the reference width w1 of the substrate layer 100 may be a length of the substrate layer 100 in the first direction (for example, the x direction). This aspect will be described in more detail below.

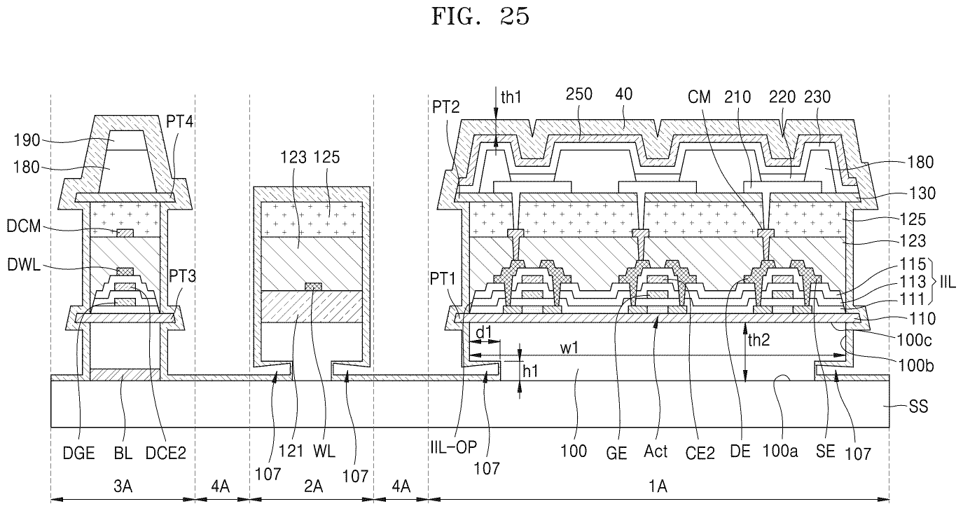

According to an embodiment, a height h1 of the side-wall groove 107 may be greater than or equal to about 150% of a reference thickness th1 (see FIG. 25) of the encapsulation layer 40 (see FIG. 25) and less than or equal to about 50% of a reference thickness th2 of the substrate layer 100. Here, the height h1 of the side-wall groove 107 may be a length between the lower surface 100a of the substrate layer 100 and the side-wall groove 107 formed by removing at least a portion of the substrate layer 100 in a thickness direction of the display apparatus 1. For example, the height h1 of the side-wall groove 107 may be a length in a third direction (for example, a z direction) crossing the first direction (for example, the x direction). Also, the reference thickness th1 of the encapsulation layer 40 may denote a thickness from a lower surface to an upper surface of the encapsulation layer 40 arranged on the capping layer 250. The reference thickness th2 of the substrate layer 100 may be a thickness from the lower surface 100a of the substrate layer 100 to the upper surface 100c of the substrate layer 100. This aspect will be described in more detail below.

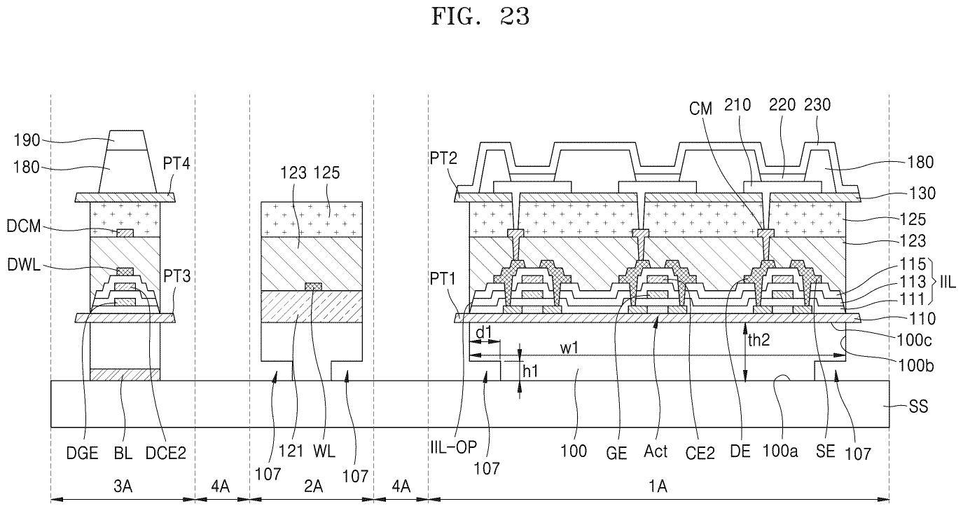

Referring to FIG. 23, the emission layer 220 may be formed on the first electrode 210 in the display area 1A, and the second electrode 230 may be formed on the emission layer 220. Although not shown, a first functional layer and a second functional layer may be respectively formed below and above the emission layer 220. Also, although not shown, the first functional layer, the second functional layer, and/or the second electrode 230 may be formed not only in the display area 1A, but also throughout the connection area 2A, the dummy area 3A, and/or the cut area 4A. For example, the first functional layer, the second functional layer, and/or the second electrode 230 may also be formed in the display area 1A and the connection area 2A. Alternatively, the first functional layer, the second functional layer, and/or the second electrode 230 may be formed in the display area 1A, the connection area 2A, the dummy area 3A, and/or the cut area 4A.

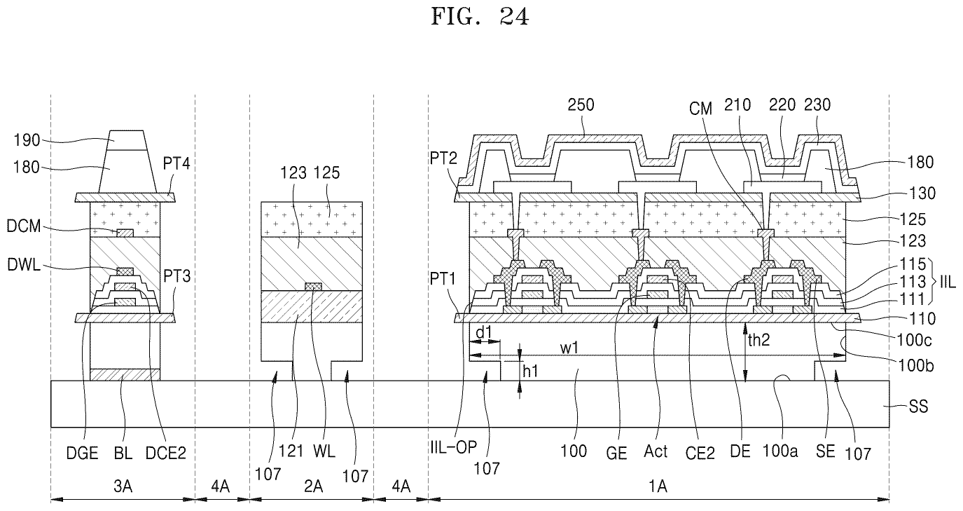

Referring to FIG. 24, the capping layer 250 may be formed on the second electrode 230 in the display area 1A. The capping layer 250 may be formed throughout the second electrode 230. According to an embodiment, the capping layer 250 may be formed only in the display area 1A. However, the disclosure is not limited thereto. For example, the capping layer 250 may be formed in the display area 1A and the connection area 2A. Alternatively, the capping layer 250 may be formed in all of the display area 1A, the connection area 2A, the dummy area 3A, and the cut area 4A.

Referring to FIG. 25, the encapsulation layer 40 may be formed on the capping layer 250. The encapsulation layer 40 may be formed throughout the display area 1A, the connection area 2A, the dummy area 3A, and the cut area 4A. As described above, the encapsulation layer 40 may include one inorganic layer. In this case, the one inorganic layer may include a single layer or multiple layers. Alternatively, the encapsulation layer 40 may include a first inorganic layer and a second inorganic layer. Alternatively, the encapsulation layer 40 may be provided as a structure in which a first inorganic layer, a second inorganic layer, and an organic layer between the first inorganic layer and the second inorganic layer are provided.

According to an embodiment, at least a portion of the encapsulation layer 40 may be formed also in the side-wall groove 107 formed in the substrate layer 100. However, disconnection or thinness of the encapsulation layer 40 may be induced in the side-wall groove 107, and thus, the thickness of the encapsulation layer 40 may be reduced to about 10%.

According to an embodiment, components of the encapsulation layer 40 may be formed on all of the upper surface, the side surface, and the lower surface. For example, the encapsulation layer 40 may be formed on an upper surface of the capping layer 250, on the side surface 100b of the substrate layer 100, and also in the side-wall groove 107. However, in this case, a thickness of the encapsulation layer 40 formed on the upper surface of the capping layer 250, a thickness of the encapsulation layer 40 formed on the side surface 100b of the substrate layer 100, and a thickness of the encapsulation layer 40 formed in the side-wall groove 107 may be different from each other. For example, a deposition speed of the encapsulation layer 40 formed on the upper surface of the capping layer 250 may be the highest, and a deposition speed of the encapsulation layer 40 formed in the side-wall groove 107 may be the lowest. In other words, when the encapsulation layer 40 is deposited during the same period of time, the thickness of the encapsulation layer 40 on the upper surface of the capping layer 250 may be the greatest, and the thickness of the encapsulation layer 40 formed in the side-wall groove 107 may be the least. However, the disclosure is not limited thereto. Also, the deposition speed of the encapsulation layer 40 in the side-wall groove 107 may be affected by the depth d1 of the side-wall groove 107.

According to an embodiment, the depth d1 of the side-wall groove 107 may be greater than or equal to about 6 μm and less than or equal to about 25% of the reference width w1 of the substrate layer 100. As the depth d1 of the side-wall groove 107 increases, the thickness of the encapsulation layer 40 may be reduced to the end of the encapsulation layer 40. When the depth d1 of the side-wall groove 107 is less than about 6 μm, the thickness of the encapsulation layer 40 may not be sufficiently reduced, and thus, disconnection of the encapsulation layer 40 may not be induced in the side-wall groove 107, or the encapsulation layer 40 may not be formed to have a small thickness in the side-wall groove 107. Thus, in the process of releasing the substrate layer 100 from the carrier substrate SS, the encapsulation layer 40 may not be released, or the encapsulation layer 40 arranged on the side surface 100b of the substrate layer 100 may be detached from the side surface 100b of the substrate layer 100. On the contrary, when the substrate layer 100 supports the components arranged on the substrate layer 100, and when the depth d1 of the side-wall groove 107 is greater than about 25% of the reference width w1 of the substrate layer 100, the ratio of the side-wall groove 107 in the substrate layer 100 may be too high, and thus, the substrate layer 100 may not support the components arranged on the substrate layer 100. That is, mechanical stability of the substrate layer 100 may not be obtained. Thus, when the depth d1 of the side-wall groove 107 is greater than or equal to about 6 μm and less than or equal to about 25% of the reference width w1 of the substrate layer 100, the thickness of the encapsulation layer 40 may be reduced to about 10%, so that disconnection of the encapsulation layer 40 or thinness of the encapsulation layer 40 may be induced, in order to easily release the substrate layer 100 from the carrier substrate SS and obtain mechanical stability of the substrate layer 100.

According to an embodiment, a height h1 of the side-wall groove 107 may be greater than or equal to about 150% of a reference thickness th1 of the encapsulation layer 40 and less than or equal to about 50% of a reference thickness th2 of the substrate layer 100. According to the disclosure, the side-wall groove 107 may be defined in the substrate layer 100, and thus, disconnection of the encapsulation layer 40 or a small thickness of the encapsulation layer 40 compared to the reference thickness th1 may be induced in order to prevent failure of releasing the encapsulation layer 40 or prevent the detachment of the encapsulation layer 40 from the side surface 100b of the substrate layer 100, in the process of releasing the substrate layer 100 from the carrier substrate SS. However, when the height h1 of the side-wall groove 107 is less than about 150% of the reference thickness th1 of the encapsulation layer 40, the height of the side-wall groove 107 may be too little, and thus, the encapsulation layer 40 arranged in the side-wall groove 107 and the encapsulation layer 40 formed on the carrier substrate SS may be connected with (or connected to) each other, so that the encapsulation layer 40 may not be released, or the encapsulation layer 40 arranged on the side surface 100b of the substrate layer 100 may be detached from the side surface 100b of the substrate layer 100, in the process of releasing the substrate layer 100 from the carrier substrate SS. However, when the height h1 of the side-wall groove 107 is greater than about 50% of the reference thickness th2 of the substrate layer 100, the ratio of the side-wall groove 107 in the substrate layer 100 may be too high, and thus, the substrate layer 100 may not support the components arranged on the substrate layer 100. That is, mechanical stability of the substrate layer 100 may not be obtained. Thus, when the height h1 of the side-wall groove 107 is greater than or equal to about 150% of the reference thickness th1 of the encapsulation layer 40 and less than or equal to about 50% of the reference thickness th2 of the substrate layer 100, disconnection of the encapsulation layer 40 or a small thickness of the encapsulation layer 40 may be induced, so as to easily release the substrate layer 100 from the carrier substrate SS, and obtain mechanical stability of the substrate layer 100.

Referring to FIG. 26, after forming the encapsulation layer 40 throughout the display area 1A, the connection area 2A, the dummy area 3A, and the cut area 4A, the substrate layer 100 may be released from the carrier substrate SS. According to an embodiment, the substrate layer 100 may be released from the carrier substrate SS by using a laser release method irradiating a laser beam onto the substrate layer 100. The laser beam may be irradiated in a direction from a lower surface of the carrier substrate SS to an upper surface of the carrier substrate SS. Thus, the laser beam may be irradiated toward the lower surface 100a of the substrate layer 100 facing the upper surface of the carrier substrate SS. A laser may include, for example, an excimer laser having a wavelength of 308 nm, a solid ultraviolet (“UV”) laser having a wavelength of 343 nm or 355 nm, etc.

According to an embodiment, the blocking layer BL may be arranged on the carrier substrate SS in the dummy area 3A, and thus, the substrate layer 100 in the dummy area 3A may not be released from the carrier substrate SS. Thus, the display panel may not include components arranged in the dummy area 3A.

When the side-wall groove 107 is not provided in the substrate layer 100, and the capping layer 250 and the encapsulation layer 40 are formed throughout the display area 1A, the connection area 2A, the dummy area 3A, and the cut area 4A, adhesion (or a bonding force) between the capping layer 250 and the encapsulation layer 40 may be low, and thus, in the process of releasing the substrate layer 100 from the carrier substrate SS, the encapsulation layer 40 may be released from the capping layer 250 in the cut area 4A, so that the extension and/or the contraction of the display panel 10 may be interrupted, and cracks occurring in a corresponding portion may be distributed to the organic light-emitting diode to damage the organic light-emitting diode.

Also, when the capping layer 250 is deposited by patterning the capping layer 250 only in the display area 1A and/or the connection area 2A, the adhesion (or the bonding force) between the encapsulation layer 40 and the carrier substrate SS may be strong, and thus, in the process of releasing the substrate layer 100 from the carrier substrate SS, the encapsulation layer 40 formed on the side surface 100b of the substrate layer 100 may be detached, and through the detached portion, damage, such as cracks, etc., may be distributed to the organic light-emitting diode OLED to cause damage to the organic light-emitting diode OLED.

According to an embodiment, the side-wall groove 107 may be defined in the substrate layer 100 to reduce the thickness of the encapsulation layer 40, so as to induce the disconnection of the encapsulation layer 40 in the side-wall groove 107 or form the encapsulation layer 40 to have a small thickness in the side-wall groove 107. By doing so, the encapsulation layer 40 may be easily released in the process of releasing the substrate layer 100 from the carrier substrate SS. Thus, the failure of releasing the encapsulation layer 40 may be effectively prevented, or the detachment of the encapsulation layer 40 from the side surface 100b of the substrate layer 100 may be effectively prevented, in the process of releasing the substrate layer 100 from the carrier substrate SS. Therefore, by forming the side-wall groove 107 in the substrate layer 100, damage to the organic light-emitting diode OLED may be prevented, and the display panel 10 (or the display apparatus 1) may be easily extended and/or contracted.

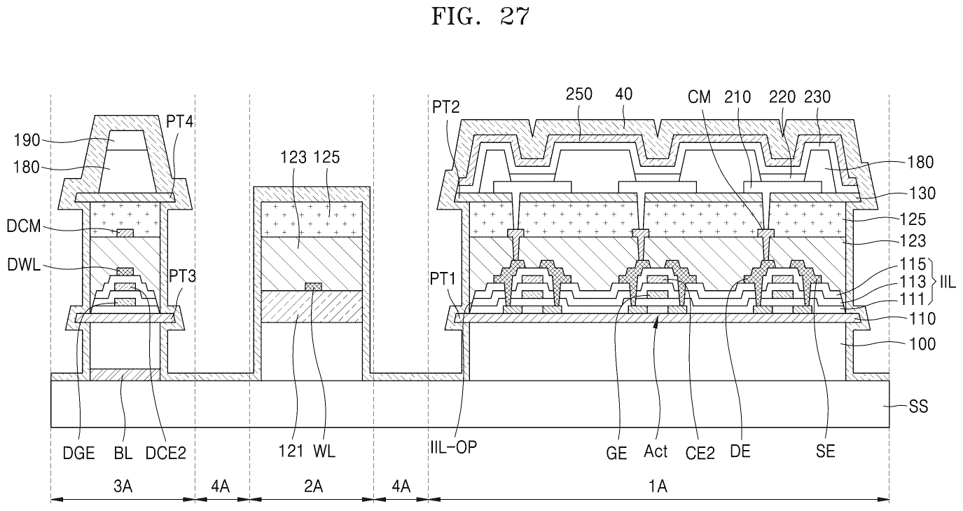

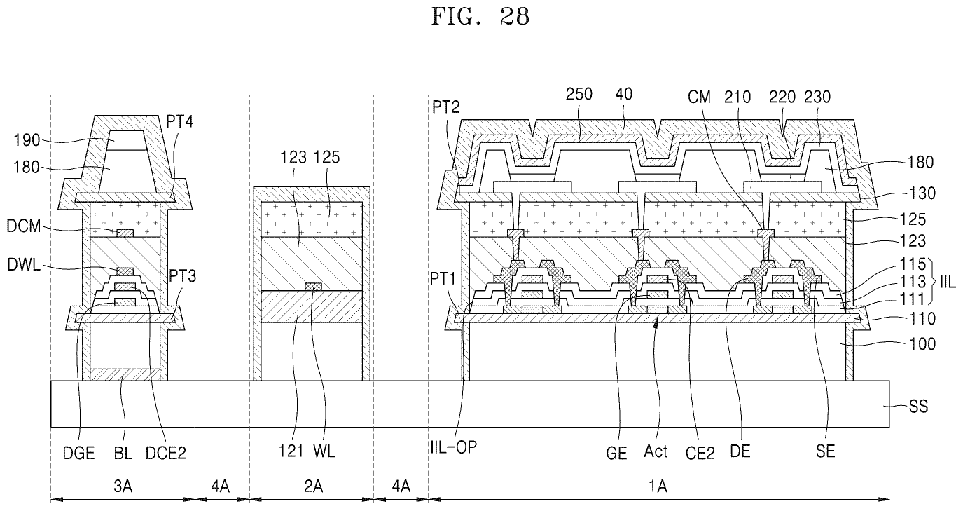

Referring to FIGS. 27 and 28, the side-wall groove 107 may not be formed in the substrate layer 100, and the encapsulation layer 40 may be formed throughout the display area 1A, the connection area 2A, the dummy area 3A, and the cut area 4A, and then, a portion of the encapsulation layer 40 formed in the cut area 4A may be removed by using an additional process to disconnect the encapsulation layer 40.

Alternatively, the encapsulation layer 40 formed in the cut area 4A may be removed by using an additional sacrificial layer.

As described above, according to the one or more of the above embodiments, the display apparatus having improved flexibility may be realized. However, the scope of the disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus including a display panel in which a penetration-opening portion is defined, the display apparatus comprising:
a substrate layer including a first display portion, a second display portion, and a connection portion connecting the first display portion to the second display portion;
a side-wall groove defined in the substrate layer and recessed from a lower surface of the substrate layer;
a pixel arranged on the first display portion; and
a line arranged on the connection portion and configured to transfer an electrical signal.

2. The display apparatus of claim 1, wherein at least a portion of the side-wall groove is provided along a circumference of the first display portion.

3. The display apparatus of claim 1, wherein at least a portion of the side-wall groove is provided along a circumference of the connection portion.

4. The display apparatus of claim 1, further comprising an encapsulation layer covering the pixel.

5. The display apparatus of claim 4, wherein a height of the side-wall groove is greater than or equal to 150% of a reference thickness of the encapsulation layer and less than or equal to 50% of a reference thickness of the substrate layer measured in a portion of the substrate layer where the side-wall groove is not defined.

6. The display apparatus of claim 1, wherein a depth of the side-wall groove in a side direction is greater than or equal to 6 micrometers (μm) and less than or equal to 25% of a reference width of the substrate layer in the side direction and measured in a portion of the substrate layer where the side-wall groove is not defined.

7. The display apparatus of claim 1, wherein the side-wall groove is provided to have a quadrangular, triangular, curved, or stair shape.

8. The display apparatus of claim 4, wherein the pixel includes a first electrode, an emission layer arranged on the first electrode, and a second electrode arranged on the emission layer.

9. The display apparatus of claim 8, further comprising a capping layer arranged on the second electrode.

10. The display apparatus of claim 9, wherein the capping layer is provided between the second electrode and the encapsulation layer.

11. The display apparatus of claim 1, further comprising a first insulating layer arranged on the first display portion of the substrate layer and including a first tip protruding toward the penetration-opening portion.

12. The display apparatus of claim 11, further comprising:
a second insulating layer arranged on the first insulating layer; and
a third insulating layer arranged on the second insulating layer and including a second tip protruding toward the penetration-opening portion.

13. A method of manufacturing a display apparatus, the method comprising:
preparing a carrier substrate including a display area, a connection area, a dummy area, and a cut area;
forming a substrate layer on the carrier substrate;
forming a first insulating layer on the substrate layer;
forming a first electrode on the first insulating layer in the display area; and
removing the first insulating layer and the substrate layer in the cut area and forming a side-wall groove in the substrate layer in the display area and the connection area.

14. The method of claim 13, wherein the side-wall groove overlaps the display area in a plan view, and at least a portion of the side-wall groove is formed along a circumference of the display area.

15. The method of claim 13, wherein the side-wall groove overlaps the connection area in a plan view, and at least a portion of the side-wall groove is formed along a circumference of the connection area.

16. The method of claim 13, further comprising, after the removing of the first insulating layer and the substrate layer in the cut area and the forming of the side-wall groove in the substrate layer in the display area and the connection area:
forming an emission layer on the first electrode;
forming a second electrode on the emission layer;
forming a capping layer on the second electrode; and
forming an encapsulation layer on the capping layer.

17. The method of claim 16, wherein the encapsulation layer is formed throughout the display area, the connection area, the dummy area, and the cut area.

18. The method of claim 17, wherein a height of the side-wall groove is greater than or equal to 150% of a reference thickness of the encapsulation layer and less than or equal to 50% of a reference thickness of the substrate layer measured in a portion of the substrate layer where the side-wall groove is not defined.

19. The method of claim 13, wherein a depth of the side-wall groove in a side direction is greater than or equal to 6 μm and less than or equal to 25% of a reference width of the substrate layer in the side direction and measured in a portion of the substrate layer where the side-wall groove is not defined.

20. The method of claim 15, wherein the side-wall groove is provided to have a quadrangular, triangular, curved, or stair shape.
